(19) United States
(12) Patent Application Publication
(10) Pub. No.: US 2026/0206336 A1
(43) Pub. Date: Jul. 16, 2026

(54) UNLOCKING HIGH PERFORMANCE, ULTRA-LOW POWER VAN DER WAALS TRANSISTORS: TOWARDS BACK-END-OF-LINE IN- SENSOR MACHINE VISION

(71) Applicants: University of Southern California, Los Angeles, CA (US); King Abdulaziz City for Science and Technology, Riyadh (SA)

(72) Inventor: Mohammed Reda AMER, Los Angeles, CA (US)

(73) Assignees: University of Southern California, Los Angeles, CA (US); King Abdulaziz City for Science and Technology, Riyadh, OT (SA)

(21) Appl. No.: 19/418,142

(22) Filed: Dec. 12, 2025

Related U.S. Application Data
(60) Provisional application No. 63/733,649, filed on Dec. 13, 2024.

(51) Int. Cl. H10F 30/282; H10F 71/00

(52) U.S. Cl. CPC H10F 30/282; H10F 71/128

(57) ABSTRACT

A phototransistor includes a substrate, a gate electrode disposed over the substrate, a gate dielectric layer disposed over the gate electrode, source and drain electrodes disposed over the gate dielectric layer, and a channel layer bridging the source and drain electrodes. The channel layer is composed of at least one van der Waals two-dimensional material contacting top surfaces of the source and drain electrodes to form a van der Waals interface. The phototransistor exhibits gate-tunable photoresponsivity enabling operation in both photovoltaic and photoconductive modes. In one embodiment, the channel layer includes a MoS₂/WSe₂ heterojunction exhibiting near-ideal diode behavior with an ideality factor of less than 2.0 and current rectification ratio of at least 10². A method of fabricating the phototransistor includes an anneal and heal treatment process to reduce contact resistance and mitigate Fermi level pinning. The phototransistor is suitable for back-end-of-line integration and in-sensor machine vision applications.

### CROSS-REFERENCE TO RELATED APPLICATIONS

This application claims the benefit of U.S. provisional application Ser. No. 63/733,649 filed Dec. 13, 2024, the disclosure of which is hereby incorporated in its entirety by reference herein.

### TECHNICAL FIELD

In at least one aspect, gate-tunable van der Waals phototransistors for in-sensor machine vision applications, and methods for fabricating the same, are provided.

### BACKGROUND

Sensory nodes are in significant demand with the rise of artificial intelligence (AI) and big-data processing. In fact, it is predicted that rapid growth in integrated sensor technologies will take place in the next few years. Driven by the intuitive desire to implement machine learning (ML) applications, on-chip AI/ML is becoming a vital part for many industries. However, current optical sensor technologies are limited by conventional van Neumann architectures, where the sensing element and the computing element are physically separated. A novel approach for the future of semiconductors is readily proposed consisting of CMOS+X where X is an emerging technology.¹ Within this context, multifunctional sensors with in-sensor and near-sensor computing have emerged as the forefront for efficient AI/ML applications.²⁻⁵

Therefore, in-sensor intelligent machine vision (MV) has the potential to revolutionize many industries, such as autonomous vehicles, robotics, and surveillance. Inspired by the human eye, MV requires preprocessing of collected information within the sensory node and without the need for analog to digital conversion (ADC). Although near-sensor and in-sensor MV are both attractive approaches, in-sensor MV exhibit more benefits than near-sensor MV including lower number of devices over a limited size, less fabrication processes, and perhaps lower power consumption. Nevertheless, most of the reported work on in-sensor MV suffers from limitations in the photodetector element, which include low performance, scalability issues, expensive or impractical fabrication processes, and noticeable power consumption. These major challenges prompt exploring a reliable photodetector element first that can be utilized for in-sensor MV, exhibit highly tunable photoresponsivity in the dedicated detection wavelength, ultralow power consumption, and back-end-of-line (BEOL)-compatible.

Advantageously, two-dimensional (2D) materials are becoming a strong candidate for such applications.6-9 Various reports have shown the capability of using 2D materials for in-sensor and near-sensor MV. Due to their atomically thin structure coupled with exceptional electronic and optical properties, 2D materials are a promising candidate for MV. Yet, a major bottleneck that prevents 2D devices from being implemented in such an application is device resistance, which suffers from Fermi level pinning (FLP) at the contacts. This challenge can affect photodetector and phototransistor properties, including the photoresponsivity magnitude and electrostatic (gate) tunability, which are some major features required to implement the in-sensor MV concept.

Accordingly, there is a need for improved sensors based on 2D materials that overcome Fermi level pinning at the contacts, exhibit gate-tunable photoresponsivity with ultra-low power consumption, and are compatible with scalable, back-end-of-line (BEOL) fabrication processes for in-sensor machine vision applications.

### SUMMARY

In at least one aspect, a new and scalable method to fabricate 2D-FET phototransistors based on a modified van der Waals (vdW) deposition lithography strategy is demonstrated. We show that van der Waals field effect transistor (vdW-FET) device resistance can be mitigated by a scalable and cost-effective treatment process called “anneal and heal,” which relies on short thermal pulses and produces relatively high performance vdW-FETs. We explore MoS₂/WSe₂ junctions in a vdW-FET configuration using our fabrication strategy and show gate-tunable, near-ideal diode behavior. We show that this phototransistor exhibits a highly tunable photoresponsivity of that can be tuned by a single gate. We finally explore optoelectronic properties of this phototransistor and demonstrate ultralow power dissipation, superseding other reported photodetector devices used for in-sensor MV applications.

In another aspect, a phototransistor, and in particular, a FET phototransistor, is provided. The phototransistor includes a substrate and a source electrode, and a drain electrode disposed over the substrate. A channel layer bridges the source electrode and the drain electrode. Characteristically, the channel layer is composed of at least one van der Waals (vdW) two-dimensional material. A gate electrode is configured to modulate an electric field across the channel layer. A gate dielectric layer is disposed between the channel layer and the gate electrode. Advantageously, the phototransistor exhibits gate-tunable photoresponsivity enabling operation in multiple modes wherein photo responsivity is adjustable by varying a gate voltage applied to the gate electrode.

In another aspect, a phototransistor, and in particular, a FET phototransistor, is provided. The phototransistor includes a substrate, a gate electrode disposed over the substrate, a gate dielectric layer disposed over the gate electrode, a source electrode and a drain electrode disposed over the gate dielectric layer, and a channel layer bridging the source electrode and the drain electrode. The channel layer is composed of at least one van der Waals (vdW) two-dimensional material. The channel layer contacts top surfaces of the source electrode, and the drain electrode forms a van der Waals interface. Advantageously, the phototransistor exhibits gate-tunable photoresponsivity enabling operation in both a photovoltaic mode and a photoconductive mode.

In another aspect, a reconfigurable optical sensor array for in-sensor machine vision applications is provided. The sensor array includes a plurality of sensor elements is provided. Advantageously, each sensor element includes the phototransistors set forth herein with gate-tunable photoresponsivity for in-sensor machine vision applications. In a refinement, the reconfigurable optical sensor array includes a plurality of sensor elements arranged in an m×n array where m is the number of sensor elements in a first linear direction and n is the number of sensor elements in a second linear direction. Each sensor element includes a phototransistor as set forth herein. Advantageously, each sensor element exhibits independently tunable photoresponsivity controllable by a gate voltage applied thereto.

In another aspect, a method for fabricating the phototransistor set forth herein is provided. The method includes steps of providing a substrate with a gate dielectric layer deposited thereon and forming a source electrode and a drain electrode on the substrate. A channel layer is placed over the source electrode and a drain electrode to bridge the source electrode and the drain electrode. As set forth above, the channel layer is composed of at least one van der Waals (vdW) two-dimensional material. A gate electrode is applied to control an electric field across the channel layer. The phototransistor is subjected to an anneal and heal treatment process to reduce device resistance and increase electronic coupling. Advantageously, the phototransistor exhibits gate-tunable responsivity and a high specific detectivity.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

For a further understanding of the nature, objects, and advantages of the present disclosure, reference should be made to the following detailed description, read in conjunction with the following drawings, wherein like reference numerals denote like elements and wherein:

FIG. 1a. Schematic view of a FET phototransistor with a single-material channel layer.

FIG. 1b. Schematic view of a FET phototransistor with a channel layer having a heterojunction.

FIGS. 2a, 2b, and 2c. Semiconductor-metal contact: (a) structure schematics and (b) energy band diagram of the vdW-FET structure with a clean interface between the 2D material and metal contact. (c) Anneal and heal process showing thermal pulse applied to a vdW-FET device.

FIGS. 3a and 3b. Performance of vdW-FETs. (a) IV_{gs} response of MoS₂ vdW-FET before and after the anneal and heal process. The inset shows IV_{ds} before and after the anneal and heal process at V_{gs}=0 V. The channel length is L=2 μm. (b) IV_{gs} response before and after the anneal and heal treatment process for WSe₂.

FIGS. 4a, 4b, 4c, 4d, and 4e. Electrical Characteristics of MoS₂ vdW-FETs. (a) IV_{gs} measurements showing the highest current obtained for MoS₂ devices with (a) L=2 μm (b) L=6 μm and (c) L=9 μm. The maximum Ion decreases with increasing channel length. (d) IV_{gs} of the MoS₂ device with Pt electrodes showing p-type behavior. (e) Benchmarking Imax vs channel length of different MoS₂ vdW-FET devices using Au with other high-performance 2D-FET devices.

FIGS. 5a, 5b, 5c, 5d, 5e, and 5f. Near-ideal diode of the MoS₂/WSe₂ vdW-FET heterojunction. (a) Schematic diagram showing MoS₂/WSe₂ junction in a vdW-FET configuration. (b) IV_{ds} before and after the anneal and heal treatment process. (c) Measured and simulated IV_{ds} using ideal diode equation. The ideality factor here is ~1.65. Evolution of (d) ideality factor and (e) rectification ratio with increasing anneal and heal treatment time. (f) IV_{gs} measured before (red curve) and after (blue curve) the anneal and heal process showing switching between a high resistive region (green shaded area) and a low resistive region (blue shaded area).

FIGS. 6a, 6b, 6c, 6d, and 6e. Gate tunability of a MoS₂/WSe₂ white light photodetector. (a) Schematics of a vdW-FET phototransistor under white light illumination. IV_{ds} measurements in the dark and under white light illumination of an MoS₂/WSe₂ vdW-FET device after being modified with vdW deposition lithography under (b) Vgs=5 V and (c) Vgs=−19 V. The inset shows the photocurrent (Iph) vs applied Vds. (d) Responsivity and (e) specific detectivity of the optical sensor at different applied Vgs and Vds.

FIGS. 7a and 7b. Benchmark of the MoS₂/WSe₂ vdW-FET photodetector technology. (a) Responsivity vs applied Vgs under photovoltaic operations (V_{ds}=0 V) of MoS₂/WSe₂ fabricated via modified vdW deposition lithography benchmarked against other MV technologies operating under photovoltaic mode. (b) Responsivity vs dissipated power of a gate-tunable MoS₂/WSe₂ white light photodetector operating in photoconductive mode benchmarked against other photodetector technologies used including Si, III-Vs, 2D materials, perovskite, etc. The highlighted pink area represents our device operating region while the light blue shaded area represents the operating region of most reported photodetectors. The dissipated power takes into account the biasing conditions of the benchmarked photodetectors when operating under dark conditions. For both plots, filled points are photodetectors used for specific wavelength(s) (λ) detection (highlighted next to the reference in Table 1). Open points with a cross inside represent white light photodetectors.

FIG. 8. Structure schematics and energy band diagram of a conventional 2D-FET device fabricated via metal evaporation on top of the 2D material. The energy band diagram shows Fermi level pinning (FLP) at the contacts.

FIGS. 9a 9b, and 9c. IV_{ds} and IV_{gs} measurements of three additional MoS₂ vdW-FET samples on Au electrodes showing enhanced device performance after the anneal and heal treatment process. Treatment time is specified in the legend of each figure.

FIG. 10. Energy band diagram of MoS₂ showing the alignment of different metal work functions with respect to the conduction and valance band energies. Values obtained from ref. [13].

FIG. 11. IV_{gs} measurements of BP vdW-FET devices on Au electrodes showing the evolution of device performance at different anneal and heal treatment times.

FIGS. 12a and 12b. IV_{gs} of two different MoS₂—Pt samples showing p-type behavior in a vdW-FET configuration after the anneal and heal treatment.

FIGS. 13a 13b, and 13c. Gate tunability mechanism and circuit of the MoS₂/WSe₂ junction. (a) IV_{gs} of MoS₂ and WSe₂ showing different n and p characteristics. These curves, when superimposed, yield the junction gate tunable profile observed in FIG. 4f (qualitatively). (b) DC circuit model of the MoS₂/WSe₂ junction showing the junction resistance tunability with external gate voltage. (c) Different cases of applied gate voltage and the condition of the junction which yield either a dominant high resistant junction, as in the case of 1 and 2, or a low resistance junction as described in case 3 where the device can be turned on. The tuning of the electrostatic doping of this junction is a key feature in modulating the photoresponsivity with gate voltage. It should be noted that the gate voltage boundaries (turn-on and turn-off voltage range) vary from device to device.

FIGS. 14a and 14b. (a) MAC operation concept illustration for in-sensor machine vision computing architecture using reconfigurable optical sensor. The operation is done by the matrix multiplication shown on the right side with the input being the optical power (P) incident on an optical sensor element with responsivity (R). The optical neuron (O) is the output current. (b) Schematic of proposed vdW-FET reconfigurable optical sensor with tunable responsivity.

FIGS. 15a, 15b, 15c, 15d, and 15e. (a) Optical image of MoS₂/WSe₂ photodetector fabricated on Au electrodes. The arrows point to the location of the Raman spectrum collected at that point showing Raman peaks signatures for each material. IV_{ds} sampled at different applied Vgs under (b) dark and (c) white light illumination. Responsivity and detectivity at different applied Vgs is shown for (d) photovoltaic mode and (e) photoconductive mode.

FIG. 16. Photodetector transient response time showing rise and fall times of 25 ms and 8 ms, respectively.

FIG. 17. Dissipated power map (P_{dark}) plotted against different applied Vgs and Vds.

FIG. 18. Schematic illustration of the device fabrication process using standard optical lithography followed by metal deposition and 2D vdW deposition on metal electrodes.

FIGS. 19a, 19b, 19c, and 19d. (a) Schematic and (b) optical image of a MoS₂ device fabricated on a vdW-FET with single gate (Au) embedded underneath Al₂O₃. (c) Raman spectrum showing signatures of MoS₂ peaks. (d) IV_{gs} measurements before and after the anneal and heal treatment process. The device exhibits pronounced p-type behavior instead of n-type readily after the treatment process. This confirms the SiO₂ contribution to n-type doping of MoS2 as reported by other groups. This observed p-type behavior is evidence of weak Fermi level pinning at the contacts, making modified vdW deposition lithography an attractive strategy.

FIG. 20. Power density vs. wavelength of white LED used in photodetector measurements. The total power density is given by integrating the area under the curve.

FIGS. 21a, 21b, 21c, 21d, and 21e. Intelligent Machine vision in action. (a) input image of Lenna image which is a standard test image used in digital image processing. (b) photocurrent map with no noise using our reconfigurable MoS2/WSe2 phototransistor. (c) edge detection using spatial filters, namely vertical, horizontal, 45 degrees, and 135 degrees. Images demonstrate edge detection enabled by in-sensor computing. (d) photocurrent map and (e) edge detection results when gaussian noise is applied to the input image. Results demonstrate our reconfigurable phototransistor capabilities of in-sensor image processing even when noise is present.

FIG. 22. Table 1 which provides a comparison of different photodetector technologies and their corresponding photodetection wavelength used in benchmarking plots in FIG. 7.

### DETAILED DESCRIPTION

Reference will now be made in detail to presently preferred embodiments and methods of the present invention, which constitute the best modes of practicing the invention presently known to the inventors. The Figures are not necessarily to scale. However, it is to be understood that the disclosed embodiments are merely exemplary of the invention that may be embodied in various and alternative forms. Therefore, specific details disclosed herein are not to be interpreted as limiting, but merely as a representative basis for any aspect of the invention and/or as a representative basis for teaching one skilled in the art to variously employ the present invention.

It is also to be understood that this invention is not limited to the specific embodiments and methods described below, as specific components and/or conditions may, of course, vary. Furthermore, the terminology used herein is used only for the purpose of describing particular embodiments of the present invention and is not intended to be limiting in any way.

It must also be noted that, as used in the specification and the appended claims, the singular form “a,” “an,” and “the” comprise plural referents unless the context clearly indicates otherwise. For example, reference to a component in the singular is intended to comprise a plurality of components.

The term “comprising” is synonymous with “including,” “having,” “containing,” or “characterized by.” These terms are inclusive and open-ended and do not exclude additional, unrecited elements or method steps.

The phrase “consisting of” excludes any element, step, or ingredient not specified in the claim. When this phrase appears in a clause of the body of a claim, rather than immediately following the preamble, it limits only the element set forth in that clause; other elements are not excluded from the claim as a whole.

The phrase “consisting essentially of” limits the scope of a claim to the specified materials or steps, plus those that do not materially affect the basic and novel characteristic(s) of the claimed subject matter.

With respect to the terms “comprising,” “consisting of,” and “consisting essentially of,” where one of these three terms is used herein, the presently disclosed and claimed subject matter can include the use of either of the other two terms.

The phrase “composed of” means “including” or “comprising.” Typically, this phrase is used to denote that an object is formed from a material.

It should also be appreciated that integer ranges explicitly include all intervening integers. For example, the integer range 1-10 explicitly includes 1, 2, 3, 4, 5, 6, 7, 8, 9, and 10. Similarly, the range 1 to 100 includes 1, 2, 3, 4 . . . 97, 98, 99, 100. Similarly, when any range is called for, intervening numbers that are increments of the difference between the upper limit and the lower limit divided by 10 can be taken as alternative upper or lower limits. For example, if the range is 1.1. to 2.1 the following numbers 1.2, 1.3, 1.4, 1.5, 1.6, 1.7, 1.8, 1.9, and 2.0 can be selected as lower or upper limits.

When referring to a numerical quantity, in a refinement, the term “less than” includes a lower non-included limit that is 5 percent of the number indicated after “less than.” A lower non-includes limit means that the numerical quantity being described is greater than the value indicated as a lower non-included limited. For example, “less than 20” includes a lower non-included limit of 1 in a refinement. Therefore, this refinement of “less than 20” includes a range between 1 and 20. In another refinement, the term “less than” includes a lower non-included limit that is, in increasing order of preference, 20 percent, 10 percent, 5 percent, 1 percent, or 0 percent of the number indicated after “less than.”

The term “one or more” means “at least one” and the term “at least one” means “one or more.” The terms “one or more” and “at least one” include “plurality” as a subset.

The term “substantially,” “generally,” or “about” may be used herein to describe disclosed or claimed embodiments. The term “substantially” may modify a value or relative characteristic disclosed or claimed in the present disclosure. In such instances, “substantially” may signify that the value or relative characteristic it modifies is within +0%, 0.1%, 0.5%, 1%, 2%, 3%, 4%, 5% or 10% of the value or relative characteristic.

The term “electrical signal” refers to the electrical output from an electronic device or the electrical input to an electronic device. The electrical signal is characterized by voltage and/or current. The electrical signal can be stationary with respect to time (e.g., a DC signal) or it can vary with respect to time.

It should be appreciated that in any figures for electronic devices, a series of electronic components connected by lines (e.g., wires) indicates that such electronic components are in electrical communication with each other. Moreover, when lines directed connect one electronic component to another, these electronic components can be connected to each other as defined above.

Throughout this application, where publications are referenced, the disclosures of these publications in their entireties are hereby incorporated by reference into this application to more fully describe the state of the art to which this invention pertains.

### Abbreviations

“vdW” means van der Waals.
“FET” means Field-Effect Transistor.
“MoS₂” means Molybdenum Disulfide.
“WSe₂” means Tungsten Diselenide.
“FLP” means Fermi Level Pinning.
“MIGS” means Metal-Induced Gap States.
“BEOL” means Back-End-Of-Line.

The term “van der Waals (vdW) two-dimensional material” refers to a material that exists in an atomic layer, where the individual atoms within the layer are strongly bonded together by covalent bonds, but the layers themselves are weakly held together by weak intermolecular forces known as van der Waals forces. In other words, van der Waals (vdW) two-dimensional material is a layered, atomically thin material where layers can be easily peeled apart due to the weak interlayer interactions.

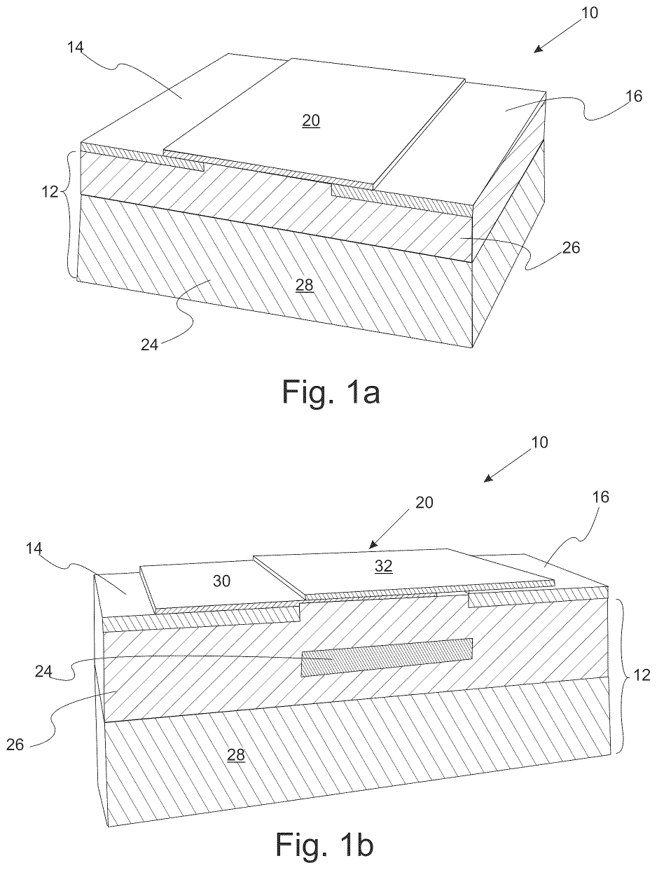

Referring to FIGS. 1a and 1b, schematics of a transistor that includes a van der Waals (vdW) two-dimensional channel are provided. In a refinement, phototransistor 10 is a FET phototransistor. Transistor 10 includes a substrate 12 with a source electrode 14 and a drain electrode 16 disposed over and typically contacting the substrate. A channel layer 20 is composed of a van der Waals (vdW) two-dimensional material bridging the source electrode 14 and the drain electrode 16. In a refinement, the at least one van der Waals two-dimensional material is composed of a component selected from the group consisting of molybdenum disulfide (MoS₂), tungsten diselenide (WSe₂), and combinations thereof. In a refinement, at least one van der Waals two-dimensional material is composed of black phosphorus (BP). A gate electrode 24 is operably configured to modulate a current through the channel layer. The gate dielectric layer 26 is disposed between the channel layer 20 and the gate electrode 24. Gate dielectric layer 26 is a thin insulating material that separates gate electrode 24 from the channel layer in the transistor. Typically made of materials like silicon dioxide (SiO₂) or high-k dielectrics, this layer prevents direct current flow between the gate and the channel. Acting as an insulator allows the gate voltage to electrostatically control the conductivity of the channel, enabling precise modulation of current flow in the transistor. FIGS. 1a and 1 b depict a variation in which substrate 12 includes gate dielectric layer 26 disposed over and typically contacting a base substrate 28 (e.g., crystalline silicon). Advantageously, the phototransistor 10 exhibits gate-tunable electrical current, enabling operation in multiple modes wherein photo responsivity is adjustable by varying a gate voltage applied to the gate electrode.

FIG. 1b depicts a variation in which channel layer 20 includes a heterojunction formed by a first two-dimensional material 30 and a second two-dimensional material 32. In a refinement, the first two-dimensional material includes molybdenum disulfide (MoS₂), and the second two-dimensional material includes tungsten diselenide (WSe₂), forming a heterojunction. In a refinement, the heterojunction exhibits near-ideal diode behavior with an ideality factor of less than 2.0 and a current rectification ratio of at least 10². Advantageously, the heterojunction provides a tunable electrical characteristics (e.g., e large channel current modulation and tunable responsivity) and efficient charge separation making phototransistor 10 suitable for high-performance transistors and optoelectronic applications.

In another aspect, the source electrode 14 and the drain electrode 16 include gold (Au), and the channel layer 20 exhibits n-type conductivity. In conventional metal-evaporated 2D-FET devices, strong Fermi level pinning (FLP) caused by metal-induced gap states (MIGS) typically force n-type behavior regardless of metal work function. However, in the vdW-FET configuration disclosed herein, the gold work function (φ~5.1 eV) initially falls within the midgap of MoS₂, resulting in minimal current flow prior to thermal treatment. After application of the anneal and heal treatment process, the conduction band minimum (CBM) of MoS₂ aligns favorably with the Au work function, facilitated in part by substrate-induced doping effects from trapped charges in the SiO₂ gate dielectric layer 26. This alignment produces a strong vdW contact exhibiting n-type conductivity with dramatically enhanced current density. In a refinement, the source electrode 14 and the drain electrode 16 are composed of platinum (Pt).

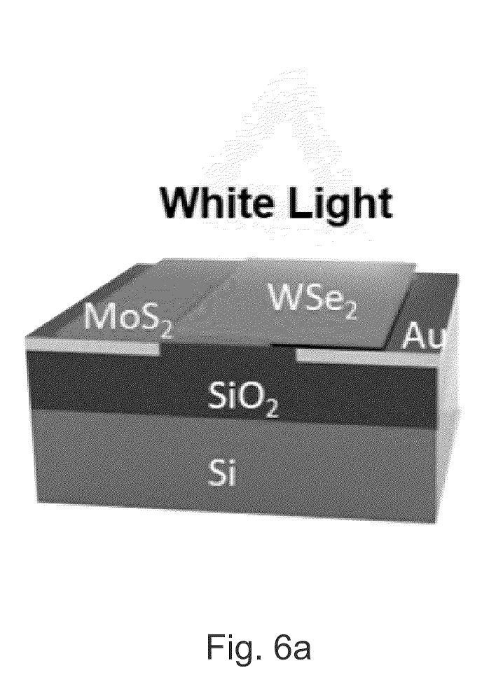

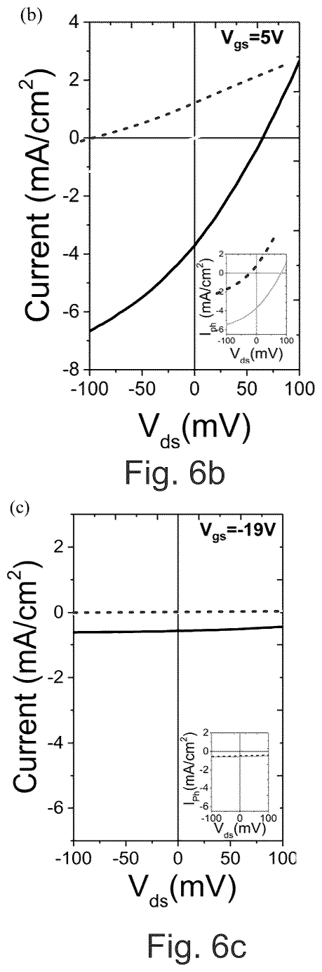

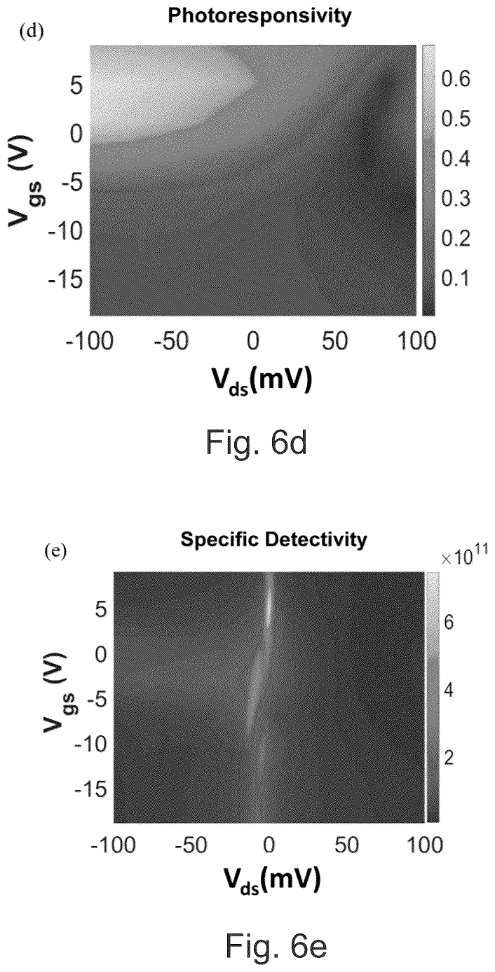

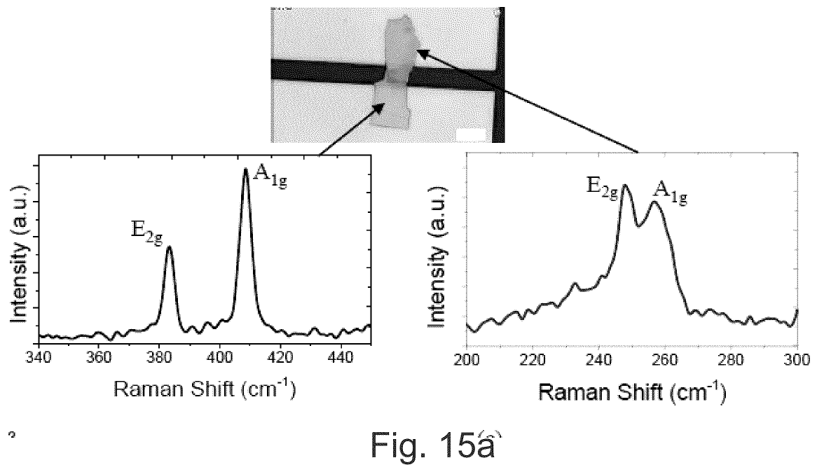

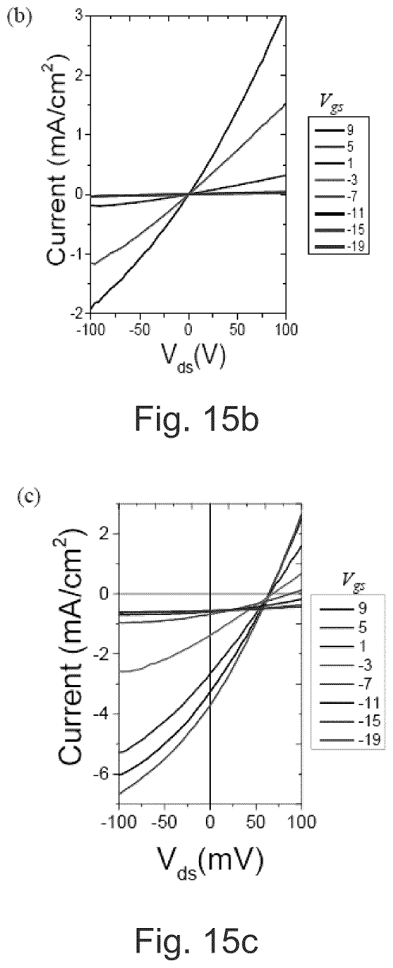

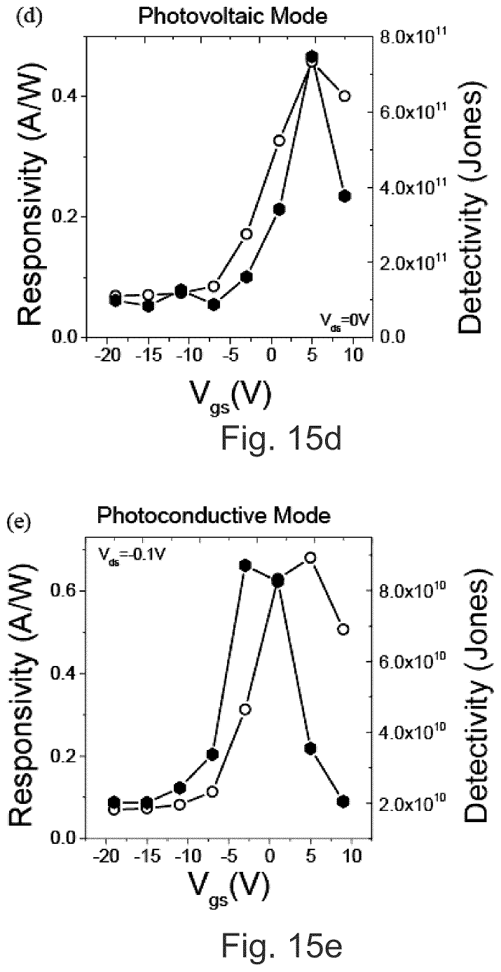

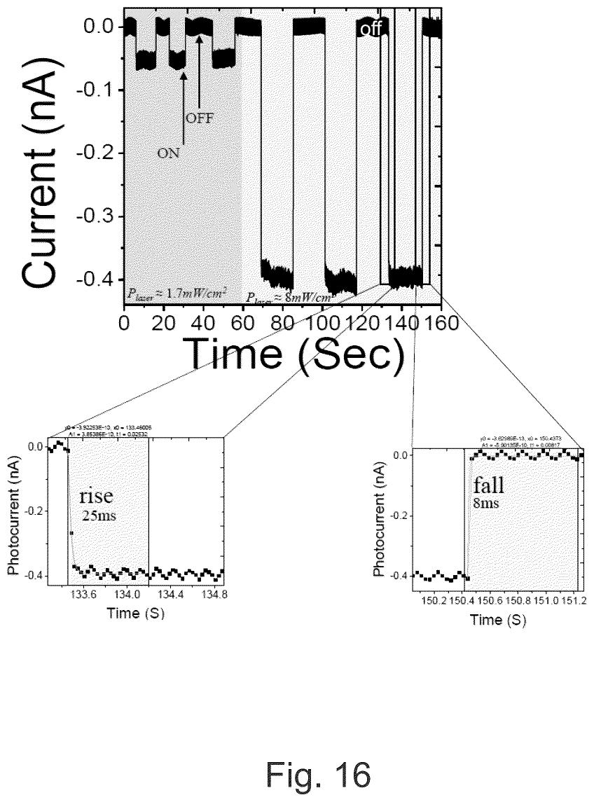

In another aspect, phototransistor 10 exhibits a specific detectivity (D*) of at least 10¹¹ Jones. The specific detectivity is calculated according to D*=RA^{1/2}/(2eI_{dark})^{1/2}, where R is the responsivity, A is the effective area of the junction, e is the electric charge, and I_{dark} is the dark current. The highest detectivity is obtained when the phototransistor operates in photovoltaic mode (V_{ds}=0 V) with the gate electrode 24 biased at V_{gs}=5 V, as shown in FIGS. 6e and 15d. This high detectivity stems from the ultra-low dark current achieved through the MoS₂/WSe₂ heterojunction in the vdW-FET configuration combined with the clean metal-semiconductor interface produced by the anneal and heal treatment process. Moreover, phototransistor 10 exhibits a rise time of less than 30 ms and a fall time of less than 10 ms. In a refinement, the rise time is approximately 25 ms and the fall time is approximately 8 ms when operating in photovoltaic mode, as demonstrated in FIG. 16.

In another aspect, channel material 20 is fabricated using a modified vdW deposition lithography process that includes an “anneal and heal” thermal treatment to reduce contact resistance and mitigate Fermi-level pinning. In a refinement, the anneal and heal process eliminates Fermi level pinning and enhances coupling between the source electrode and the drain electrode and the channel layer. In a refinement, the anneal and heal process includes exposing the phototransistor to pulsed thermal treatment at a temperature of 300° C. to 350° C. for a duration of 2 to 5 seconds. Advantageously, phototransistor 10 exhibits low-bias resistance that is proportional to channel length, with an on/off current ratio (Ion/Ioff) of at least 10² and an enhanced turn-on current density (Ion) by a factor of at least 30 compared to a phototransistor of analogous design to phototransistor 10 not treated with an “anneal and heal” thermal treatment process. In this context, bias resistance refers to the device's electrical resistance, specifically at low applied voltages (low-bias conditions). This resistance reflects how easily current can flow through the channel material (e.g., MoS₂) between the source and drain electrodes when a small voltage bias is applied.

The “modified vdW deposition” is an optimized fabrication technique designed to enhance the performance of van der Waals (vdW) field-effect transistors (FETs). This approach combines optical lithography, which is used to pattern (i.e., define) the source electrode 14 and drain electrode 16 with depositing of the source electrode 14 and the drain electrode 15 with the placement of a van der Waals two-dimensional channel 20 is placed over the source electrode and the drain electrode over the electrodes and substrate. Unlike traditional fabrication methods, this process minimizes structural damage and defects during deposition, ensuring a cleaner and more effective interface. A key component of this technique is the anneal and heal process, a thermal treatment involving a short thermal pulse at approximately 300 to 350° C. This treatment significantly enhances the metal-semiconductor interface by reducing contact resistance, eliminating defects, and mitigating Fermi Level Pinning (FLP). The method also ensures a dangling-bond-free interface between the metal electrodes and the vdW material, minimizing Metal-Induced Gap States (MIGS) that contribute to FLP. This clean interface allows for better band alignment and improved charge injection. Importantly, the modified vdW deposition is scalable and suitable for back-end-of-line (BEOL) integration, making it compatible with existing CMOS technologies. It facilitates high-throughput manufacturing by eliminating the need for complex and costly techniques like electron-beam lithography. The effectiveness of this technique is demonstrated by the fabrication of high-performance vdW-FETs with enhanced current density (Ion), reduced resistance, and improved on/off ratios (Ion/Ioff). The modified vdW deposition method significantly advances scalable, CMOS-compatible fabrication of vdW-based electronic devices.

The “anneal and heal” process is a thermal treatment technique designed to improve the electrical and interfacial properties of phototransistor 10. In this method, the fabricated phototransistor is exposed to a thermal pulse at a temperature of approximately 300 to 350° C. for a duration of 2 to 5 seconds, followed by rapid cooling to prevent structural degradation of channel layer 20. The anneal and heal process is performed in an ambient environment. This treatment may eliminate defects and impurities at the interface between source electrode 14 and drain electrode 16 and channel layer 20, which are known to cause high contact resistance and Fermi level pinning (FLP). By mobilizing trapped charges and realigning the energy bands at the interface, the anneal and heal process reduces the Schottky barrier height and enhances coupling between the metal electrodes and channel layer 20. This leads to a dramatic reduction in contact resistance, linear low-bias resistance behavior (i.e., ohmic), and enhanced current density (Ion) by a factor of at least 10³. The current on-off ratio (Ion/Ioff) is similarly enhanced, increasing from negligible values to at least 10² for MoS₂ and up to 10⁴ for WSe₂.

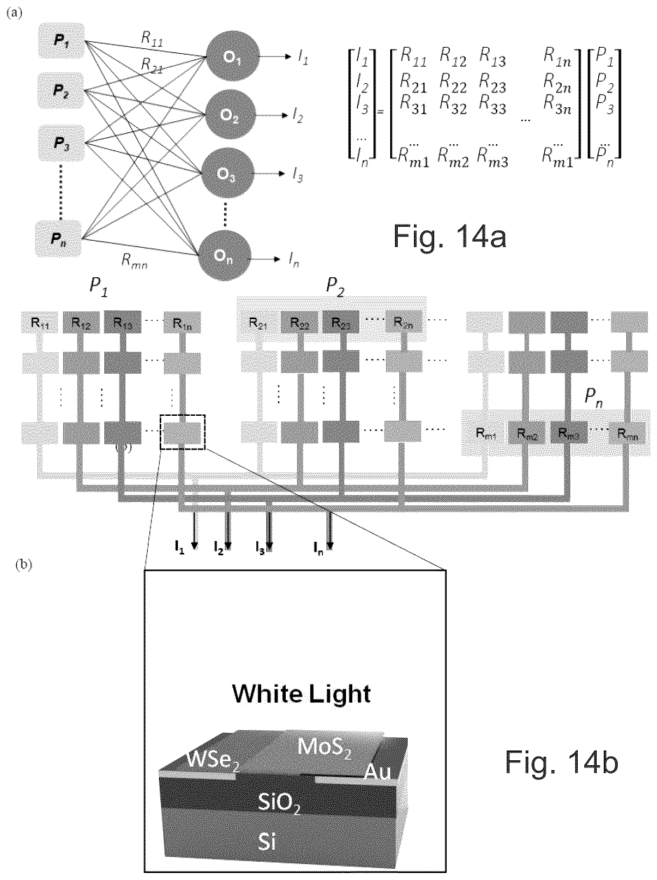

In another aspect, phototransistor 10 is configured to detect white light illumination with high efficiency. The MoS₂/WSe₂ heterojunction of channel layer 20 utilizes multilayer MoS₂ and WSe₂ to provide absorption across the entire visible spectrum. Phototransistor 10 features gate-tunable photoresponsivity, with gate electrode 24 enabling responsivity modulation of at least 6.6-fold in photovoltaic mode and at least 9.68-fold in photoconductive mode. The gate tuning ratio reaches 38.2 mA/V in photovoltaic mode and 53.5 mA/V in photoconductive mode. Phototransistor 10 further exhibits ultra-low power dissipation, defined as P_{d}=I_{dark}V_{ds}, with zero power dissipation achieved in photovoltaic mode (V_{ds}=0 V) where a short-circuit current is generated under illumination. This combination of broad spectral response, high gate tunability, and minimal power consumption renders phototransistor 10 well-suited for energy-efficient optoelectronic applications and in-sensor machine vision processing tasks, including multiply-and-accumulate (MAC) operations as illustrated in FIG. 14.

In another aspect, phototransistor 10 operates in both a photovoltaic mode and a photoconductive mode. This dual-mode functionality allows for flexible adaptation to various light detection scenarios, enhancing the photodetector's applicability across diverse optoelectronic systems. In photovoltaic mode, the drain-source voltage is zero (V_{ds}≤0 V) and a short-circuit current (I_{sc}) is generated under white light illumination without external power input, achieving a responsivity of up to 0.45 A/W. It also offers a responsivity modulation of at least 6.6-fold, enabling efficient light-to-current conversion. In photoconductive mode, a reverse bias voltage is applied across source electrode 14 and drain electrode 16, generating additional photogenerated carriers that yield higher photocurrent and enhanced responsivity of up to 0.68 A/W with a responsivity modulation of at least 9.68-fold. This dual-mode functionality allows phototransistor 10 to be adapted to various light detection scenarios: photovoltaic mode is favorable for energy-harvesting and autonomous sensor applications where zero power dissipation is preferred, while photoconductive mode provides enhanced sensitivity suitable for precision light detection in low-light environments. In both modes, gate electrode 24 provides tunable photoresponsivity, enabling flexible operation across diverse optoelectronic systems and in-sensor machine vision applications. In another aspect, in photoconductive mode, the photodetector achieves a responsivity of up to 0.68 A/W, with a responsivity modulation of at least 9.68-fold. This mode provides enhanced sensitivity under reverse bias conditions, making it suitable for precision light detection in low-light environments.

In another aspect, gate electrode 24 is capable of switching channel layer 20 between a high resistive state and a low resistive state. The high resistive state occurs when gate electrode 24 is biased in the negative regime (−10 V>V_{gs}>−4 V), producing a current density lower than 0.01 A/cm². The low resistive state occurs when the gate voltage is in the range of −4 V<V_{gs}<10 V, with a maximum current density of up to 0.78 A/cm². This gate-tunable switching enables a current change of at least 78-fold between the high and low resistive states, allowing for highly controlled electronic operations and providing a key mechanism for modulating photoresponsivity in in-sensor machine vision applications.

In another aspect, the modified vdW deposition lithography process employed in fabricating phototransistor 10 is scalable for back-end-of-line (BEOL) integration with complementary metal-oxide-semiconductor (CMOS) technology. The fabrication process utilizes optical lithography to pattern source electrode 14 and drain electrode 16, eliminating the need for electron beam lithography or other complex and expensive lithographic processes that can hinder large-scale device integration. This cost-effective approach, combined with the anneal and heal treatment process performed in ambient conditions, provides a scalable platform suitable for high-throughput manufacturing. In principle, the modified vdW deposition lithography technique can be extended to wafer-scale 2D materials such as chemical vapor deposition (CVD)-grown MoS₂ and WSe₂, enabling CMOS+2D integration for multifunctional sensor applications.

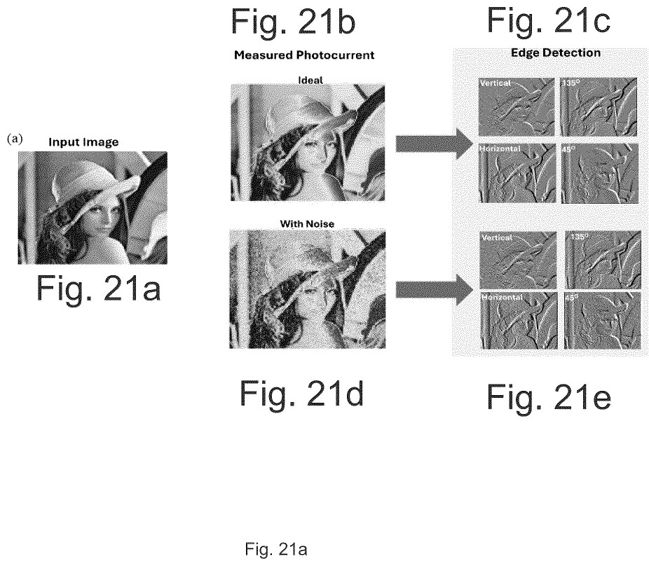

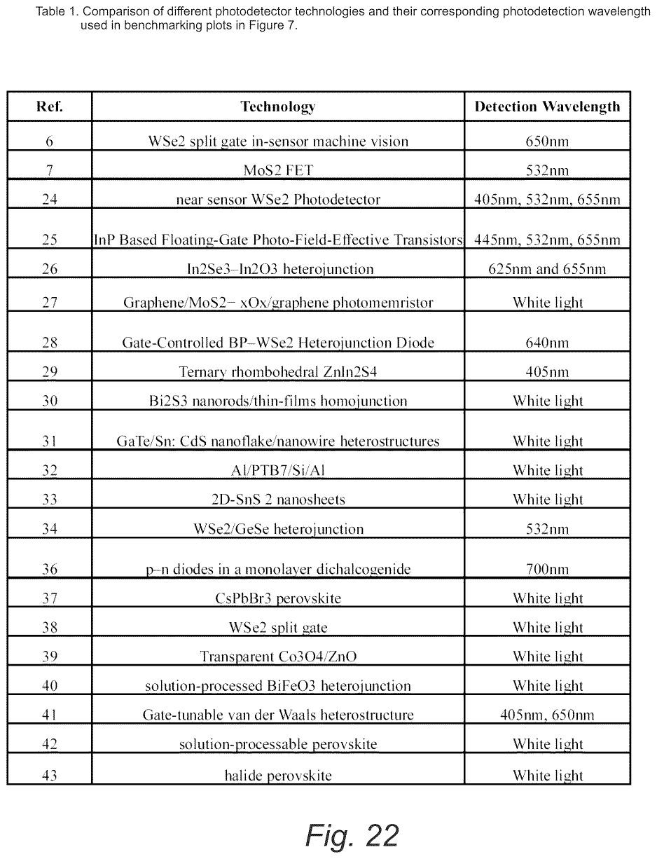

In another aspect, a reconfigurable optical sensor array for in-sensor machine vision applications is provided. The sensor array includes a plurality of sensor elements arranged in an m×n configuration, where m is the number of sensor elements in a first linear direction and n is the number of sensor elements in a second linear direction. Each sensor element includes phototransistor 10 as set forth herein, with each sensor element exhibiting independently tunable photoresponsivity (Rₘₙ) controllable by a gate voltage applied to gate electrode 24. The tunable responsivity of each sensor element emulates synaptic weights of a neural network, enabling multiply-and-accumulate (MAC) operations to be performed directly at the sensor level according to Equation 1:

$${I}_{n} = {\sum }_{n = 1}^{N} {I}_{m n} = {\sum }_{n = 1}^{N} {R}_{m n} {P}_{n} \qquad ( 1 )$$

where Pₙ is the optical power incident on each sensor element and Iₙ is the summation output current representing the optical neuron response, as illustrated in FIG. 14. This in-sensor computing architecture enables image processing tasks such as edge detection to be performed within the sensor array itself, as demonstrated in FIG. 21, thereby reducing power consumption compared to conventional von Neumann architectures where the sensing element and computing element are physically separated.

In another embodiment, a method for fabricating phototransistor 10 set forth in FIGS. 1a and 1b is provided. The method includes steps of providing substrate 12 including gate electrode 24 and gate dielectric layer 26 disposed over gate electrode 24 and depositing source electrode 14 and drain electrode 16 on gate dielectric layer 26. Channel layer 20 is placed over and in contact with source electrode 14 and drain electrode 16 to bridge source electrode 14 and drain electrode 16. In a refinement, channel layer 20 is composed of at least one van der Waals (vdW) two-dimensional material. In a refinement, phototransistor 10 is subjected to an anneal and heal treatment process including applying a thermal pulse to reduce device resistance and increase electronic coupling between channel layer 20 and source electrode 14 and drain electrode 16. Advantageously, phototransistor 10 exhibits gate-tunable responsivity and a high specific detectivity as shown in FIGS. 15d and 15e.

In another aspect of the method, the anneal and heal treatment process involves exposing channel layer 20 to a thermal pulse at approximately 300 to 350° C. for 2 to 5 seconds, followed by rapid cooling. In a refinement, the anneal and heal treatment process is performed in an ambient environment (e.g., in air). This step enhances the electrical interface quality, eliminates Fermi level pinning, and improves coupling between source electrode 14 and drain electrode 16 and channel layer 20. The process can be repeated for multiple cycles to optimize device resistance and photoresponsivity while ensuring scalability of the fabrication process.

In another aspect of the method, channel layer 20 includes a heterojunction formed from first two-dimensional material 30, such as molybdenum disulfide (MoS₂), and second two-dimensional material 32, such as tungsten diselenide (WSe₂). This combination optimizes electronic and optical properties, enabling advanced device performance. The vdW two-dimensional materials are deposited onto substrate 12 using a dry transfer method, facilitating high-quality layer assembly.

In another aspect of the method, source electrode 14 and drain electrode 16 are patterned using optical lithography, followed by metal deposition, ensuring precise electrode formation. Gate dielectric layer 26 includes silicon dioxide (SiO₂) with a thickness of approximately 300 nm, ensuring reliable gate operation. The method includes encapsulating phototransistor 10 with a protective layer after the anneal and heal treatment to preserve performance and longevity.

In another aspect of the method, phototransistor 10 is configured for operation in photovoltaic and photoconductive modes by tuning the gate voltage applied to gate electrode 24 after fabrication. The photovoltaic mode generates a short-circuit current under illumination without requiring external power, making it efficient for energy-harvesting applications. In this regard, in the photovoltaic mode, phototransistor 10 generates a short-circuit current under illumination at zero drain-source voltage; and in the photoconductive mode, phototransistor 10 operates under reverse bias to achieve enhanced photoresponsivity. The photoconductive mode, under reverse bias conditions, achieves enhanced photoresponsivity, providing superior light-detection performance even in low-light environments.

In another aspect, the method includes characterizing the electrical performance of phototransistor 10 by measuring current-voltage characteristics before and after the anneal and heal treatment. Additionally, the vdW deposition method is scalable for back-end-of-line (BEOL) integration with complementary metal-oxide-semiconductor (CMOS) technology, supporting large-scale manufacturing.

In another aspect of the method, phototransistor 10 includes substrate 12, source electrode 14 and drain electrode 16, and a vdW heterojunction of MoS₂ and WSe₂ forming channel layer 20. Gate electrode 24 modulates photocurrent, providing gate-tunable responsivity for white light detection with ultra-low power dissipation, enabling its use in energy-efficient optoelectronic systems.

Additional details are found in Olaiyan Alolaiyan, Shahad Albawardi, Sarah Alsaggaf, Thamer Tabbakh, Frank W. DelRio, and Moh. R. Amer; Unlocking High-Performance, Ultra-Low Power van der Waals Photo-Transistors: Toward Back-End-of-Line in-Sensor Machine Vision Applications; ACS Applied Materials & Interfaces 2024 16 (31), 41310-41320; DOI: 10.1021/acsami.4c07231 and its related supplemental information; the entire disclosure of which is hereby incorporated by reference.

The following examples illustrate the various embodiments of the present invention. Those skilled in the art will recognize many variations that are within the spirit of the present invention and the scope of the claims.

### Results

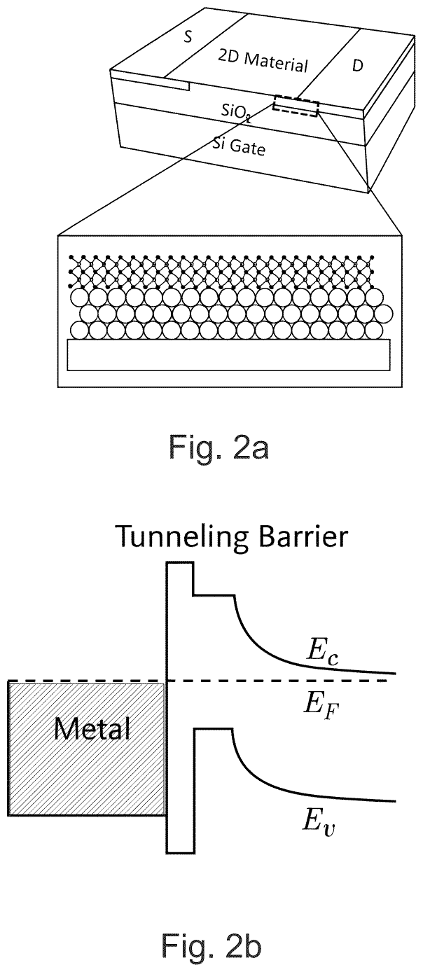

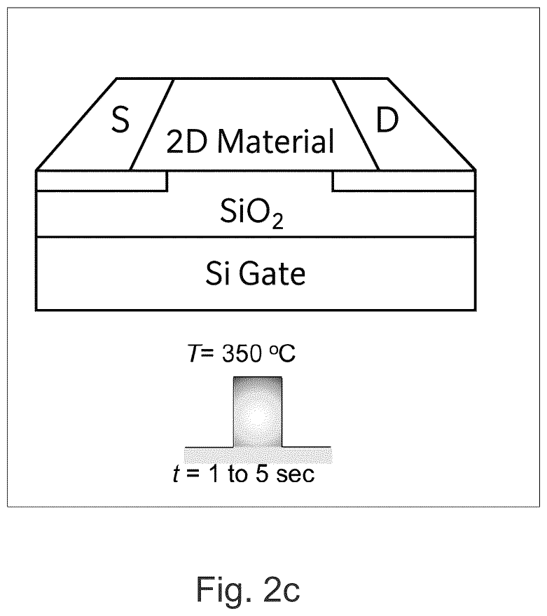

Conventional 2D-FETs vs vdW-FETs. One of the major hurdles preventing 2D-FETs from CMOS integration is device resistance. Conventional metal evaporation on 2D materials can induce structural damage and defects on the targeted 2D material, which causes metal-induced gap states (MIGS) leading to FLP. FIG. 2a demonstrates the energy band diagram of a conventional MoS₂ device fabricated using this method.¹⁰ Nevertheless, recent investigations by different groups have shown that it is possible to significantly reduce MIGS and FLP by using semimetals such as bismuth (Bi) or antimony (Sb) with (011̅2̅) orientation.^{11,12} Although the use of these semimetals is a promising approach for ultralow contact resistance, there is ambiguity lingering in terms of manufacturing scalability, cost effectiveness, and integration for in-sensor computing/MV.

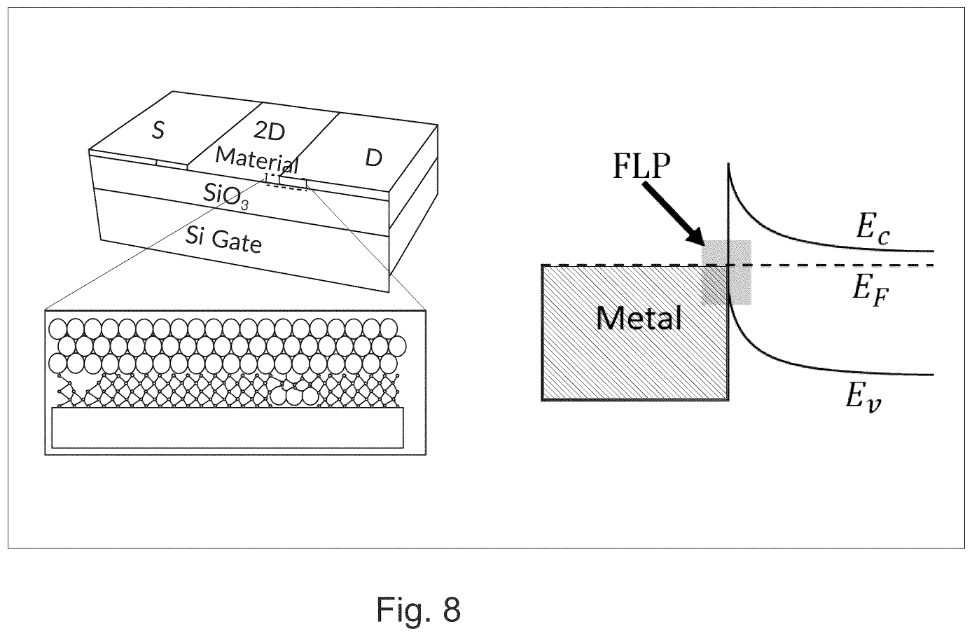

In contrast, the vdW-FET structure is shown in FIG. 8a. Here, electrodes were patterned via optical lithography with the 2D material deposited on top of the source and drain electrodes, as shown schematically in the figure. Due to the dangling-free bonds on the surface of 2D materials, the interface between the 2D material and the metal electrode is vdW (hence the name). Here, the energy band diagram after 2D deposition leads to nonlinear current-voltage characteristics and hence a large device resistance. This high resistance stems from the Schottky barrier between the 2D material and the metal electrode as well as the existence of a vdW gap at the boundaries. This vdW gap leads to the formation of a tunnel barrier, which imposes significant restrictions on the carrier transport and leads to limited attained current in the channel. FIG. 2b demonstrates this energy band diagram.

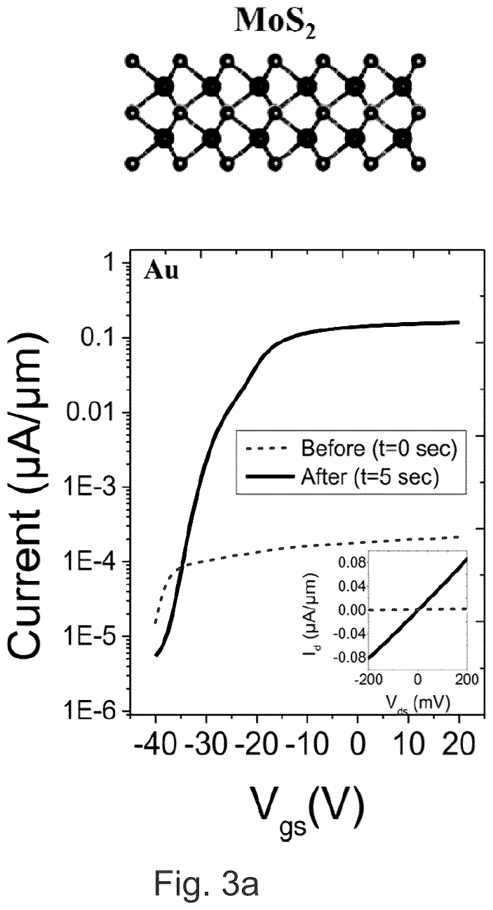

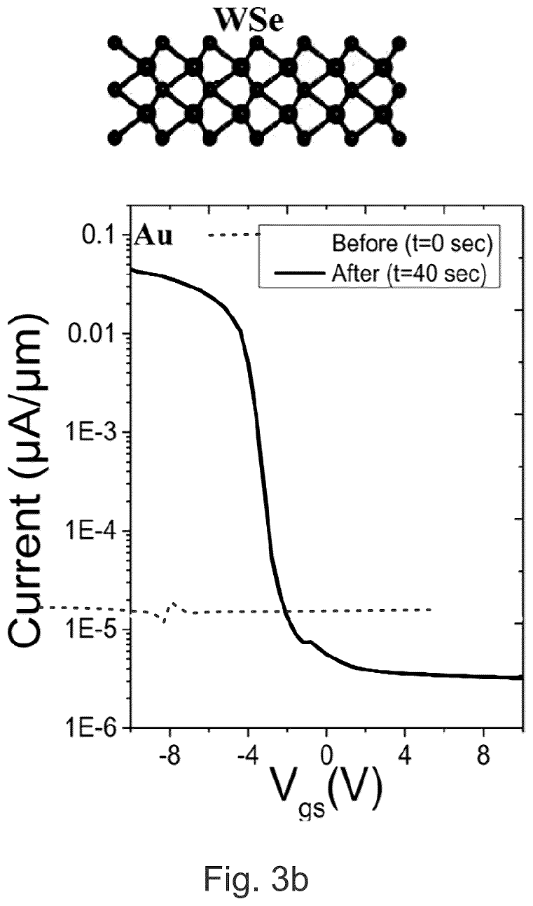

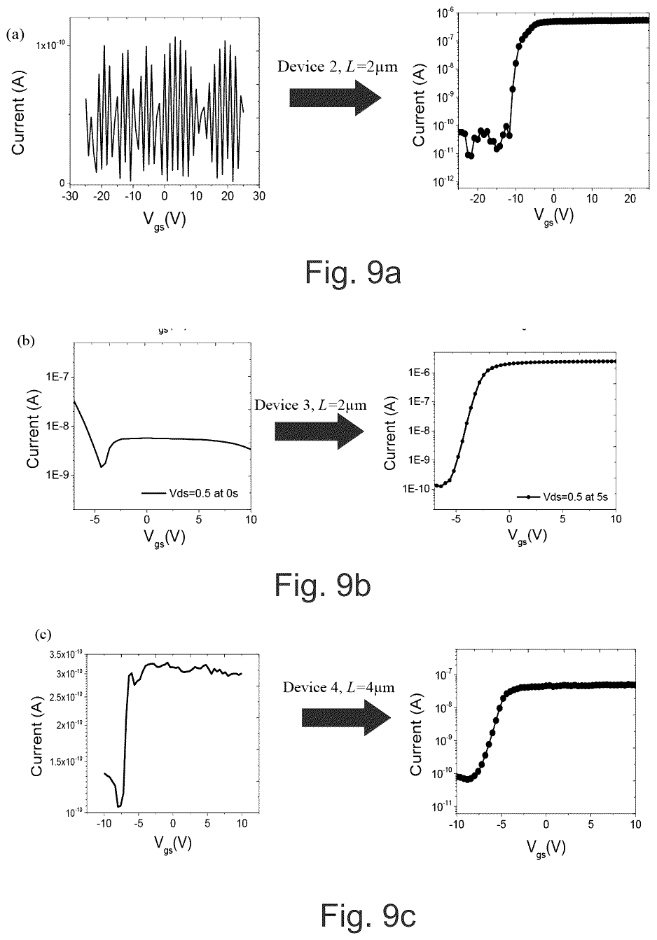

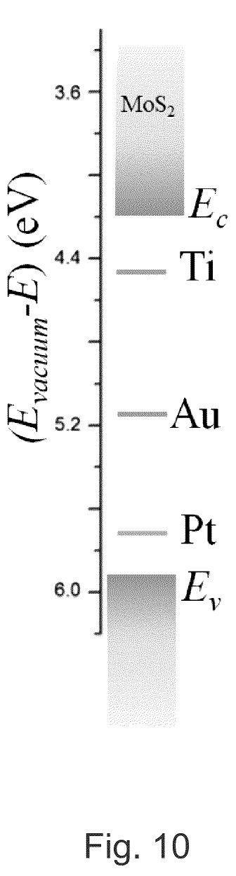

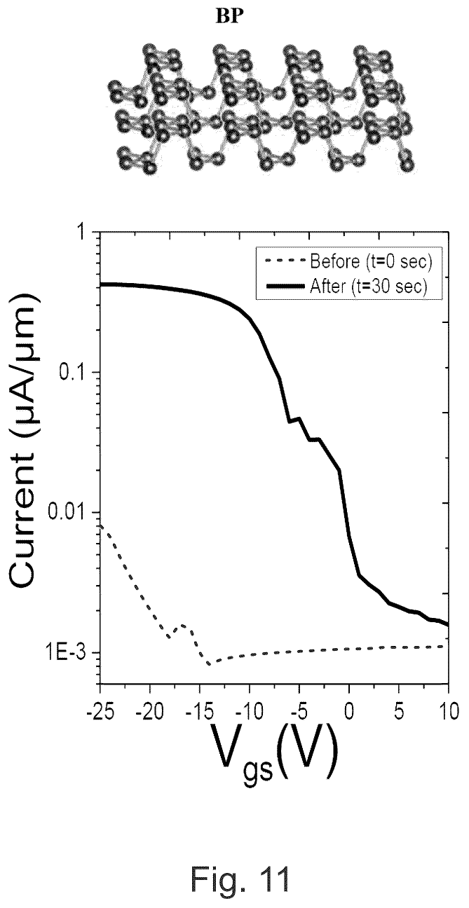

The nonlinear current-voltage behavior of vdW-FETs is shown in the electrical characteristics of the MoS₂ vdW-FETs in FIG. 3 (red curves) for IV_{gs} and IV_{ds} (inset figure). In fact, some devices showed no current flow (open circuit) in the channel, as shown in FIG. 9a. This high device resistance was attributed to the weak bonding between the metal electrodes and MoS₂. It stemmed from the nature of vdW alignment of the Au metal work function to the middle of the gap of MoS₂, as shown in FIG. 10 and discussed elsewhere.¹³ To mitigate this high-resistance effect, we developed a new scalable treatment strategy using a pulsed thermal annealing technique. Here, fabricated vdW-FET devices were exposed to a thermal pulse with temperatures of 300 to 350° C. for a few seconds (usually 2 to 5 s) followed by rapid cooling, as demonstrated schematically in FIG. 2c (see Methods and Materials for more information). The results of the anneal and heal method are shown in FIG. 2a (blue curves) for IV_{gs} and IV_{ds} (inset figure) of the MoS₂ vdW-FET device. A dramatic increase in the device's electrical performance was observed. The measured low bias resistance became linear. In fact, for large channel devices, applying higher V_{ds} resolved the current saturation. The observed Iₒₙ in FIG. 3a was enhanced by an order of at least 10³. We attribute this current enhancement to the strong coupling between the contact resistance and metal electrodes after the “anneal and heal” treatment process.

Our developed treatment process was also effective on other 2D materials such as WSe₂ and BP. This is demonstrated in FIGS. 3b for WSe₂. Here, IV_{gs} before and after the “anneal and heal” treatment process showed enhanced device performance for both materials. The maximum current density Iₒₙ and current on-off ratio Iₒₙ/I_{off} showed dramatic increases after the treatment process. That is, Iₒₙ increased by 3270 for WSe₂ and 52 for BP, while the Iₒₙ/I_{off} ratio increased from 0 to 10⁴ for WSe₂ and 8.1 to 10² for BP. Accordingly, this treatment process to mitigate device resistance is scalable and cost-effective, rendering the approach desirable for low-cost, large-scale applications.

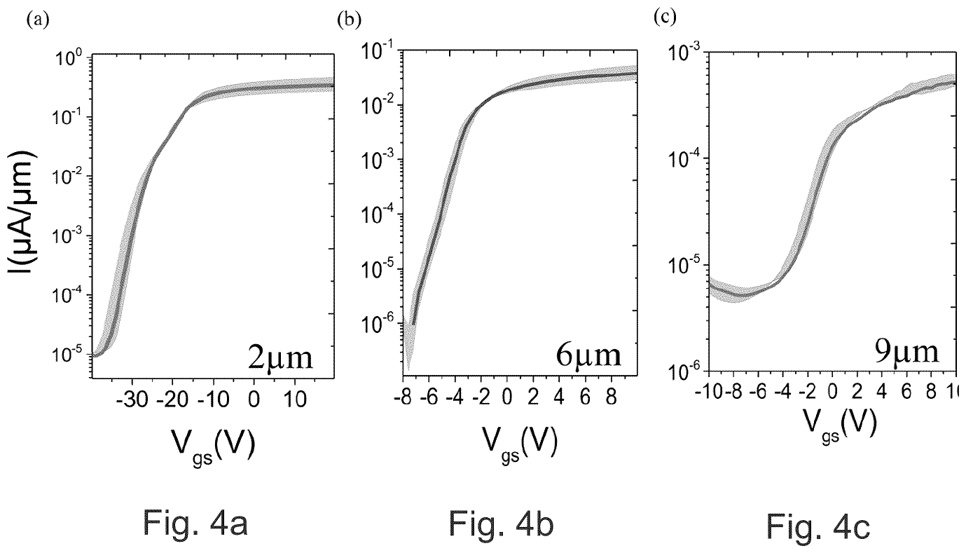

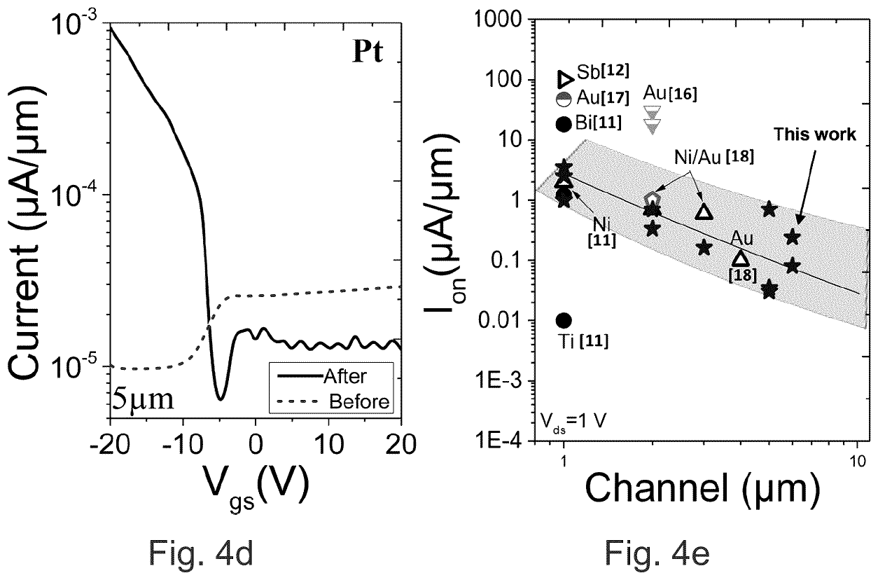

vdW-FET Device Performance. To elucidate the vdW-FET device performance after the “anneal and heal” treatment process, we carried out systematic measurements of different channels using MoS₂ vdW-FETs, as shown in FIG. 4a-c. Three different devices were fabricated with different channel lengths, mainly 2, 6, and 9 μm. For all devices, the gate electrode and dielectric thickness were kept constant (300 nm). We observed a monotonic decrease in Iₒₙ with increasing channel length. This trend was expected since increasing channel length increased free carriers scattering effects and hence, lower attainable current.

It is worth mentioning that almost all MoS₂ devices reported in the literature show n-type conductivity regardless of the metal type.^{10,14} This behavior was attributed to strong FLP caused by MIGS. Ideally, in a vdW metal-semiconductor junction, different metals with different work functions (p) give rise to different conductivity profiles, which was attributed to alignment of the metal work function to the valence or the conduction band.¹³ For instance, for Pt electrodes (φ≈5.6 eV) with MoS2 nanosheets, the valence band aligns with the Pt work function, giving rise to p-type conductivity. This behavior has been previously observed in vdW contacts.¹⁰

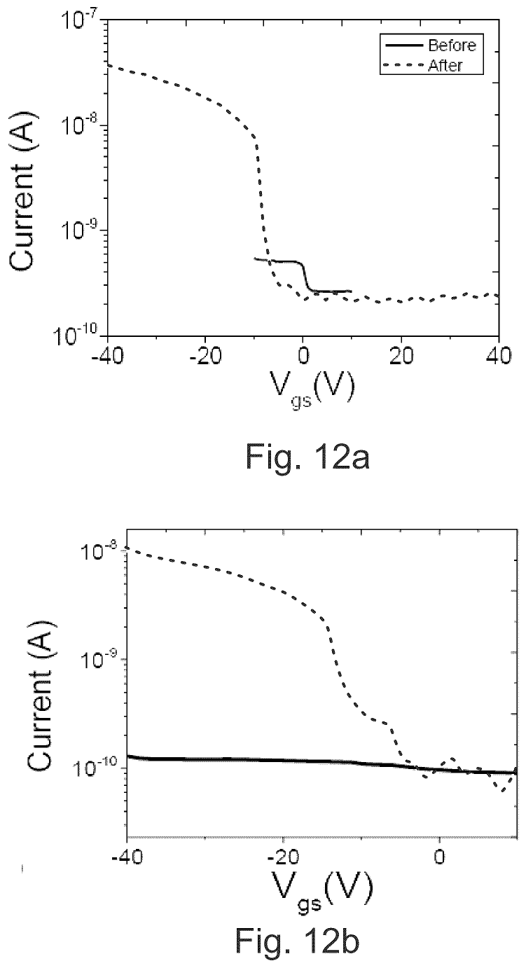

To shed some light on the nature of our vdW-FET contacts after the “anneal and heal” treatment process, we fabricated MoS₂ devices with a high work function metal (Pt). In FIG. 4d, we show the IV_{gs} of a MoS₂ device with Pt electrodes before and after the treatment process. Before any treatment, the device exhibited low current, analogous to Au—MoS₂ devices. After treatment, however, the device exhibited a strong p-type profile with an improved Iₒₙ/Ioff ratio reaching 10² and enhanced turn-on current by at least 32×. FIG. 12 shows additional vdW-FET devices with Pt electrodes displaying a similar trend. This observed p-type conductivity of vdW-FETs was in contrast to Pt—MoS₂ devices fabricated via the metal evaporation method, which predominantly showed n-type behavior due to strong FLP. We attributed this observed p-type behavior to evidence of weak FLP and a clean interface between the metal and 2D material after the anneal and heal treatment process.

Our vdW-FETs based on MoS₂ exhibited relatively competitive device performance compared to those in the literature. This is demonstrated in FIG. 4e where the highest Iₒₙ is plotted at different channel lengths and compared to other high-performance MoS₂ devices.^{11,12,15-18} The shaded pink area shows the expected Iₒₙ region of vdW-FETs with different channel lengths. This area also overlaps with other reported high-performance MoS₂ 2D-FET devices with different metals. What distinguishes vdW-FET devices here is the simplicity of fabricating these vdW-FETs that yield cost-effective solutions and a scalable platform for 2D-FETs. In addition, vdW-FETs exhibit weak FLP with conventional metals, a drawback found in many reported MoS2 transistors.

Thus, we believe this modified vdW deposition lithography strategy is appealing to produce high-performance scalable phototransistors and photodetectors for different BEOL optoelectronic applications.

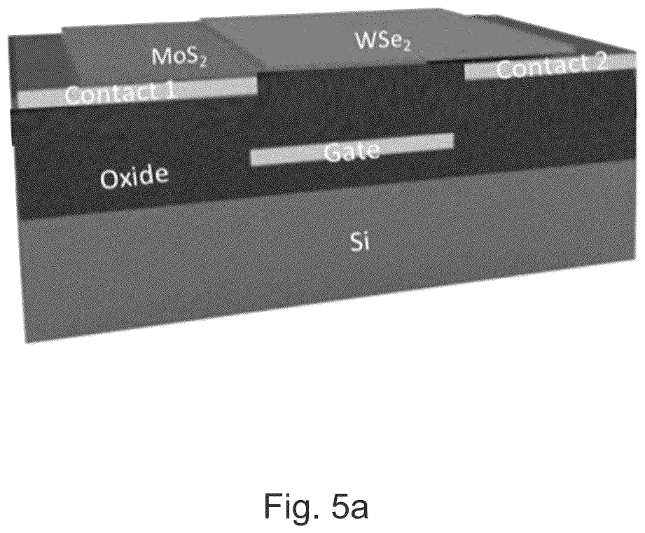

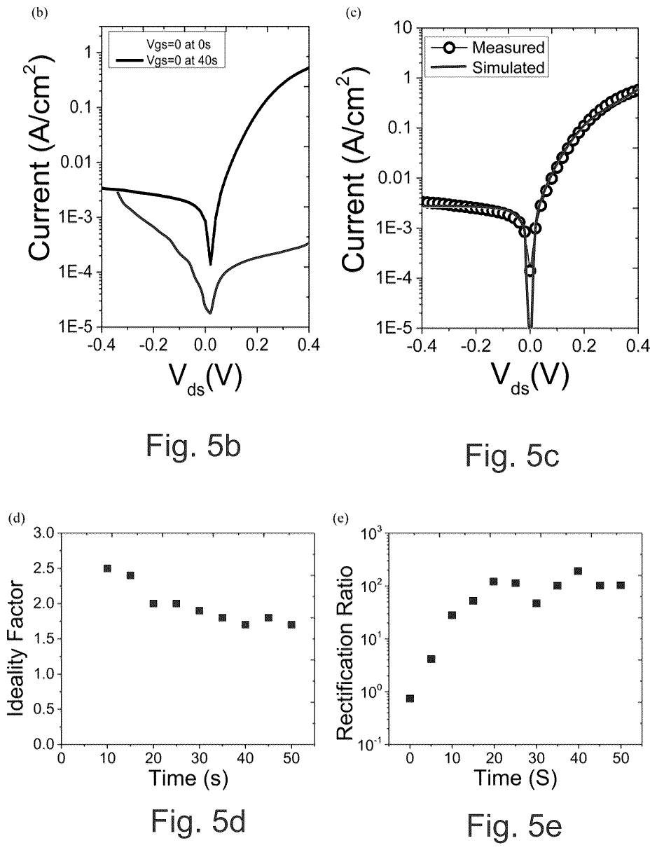

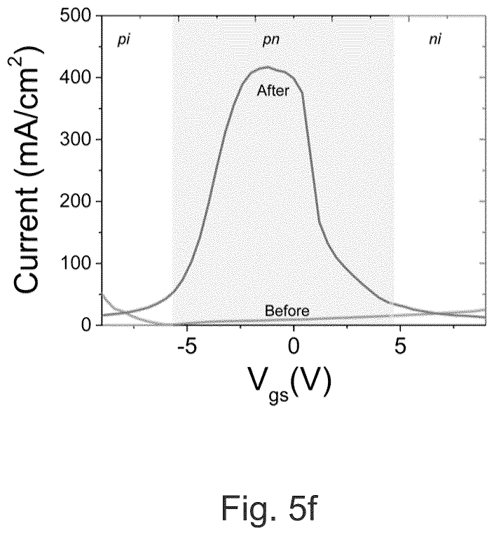

Electron Transport of MoS₂/WSe₂ vdW-FETs with a Near-Unity Ideality Factor. To gain a deeper understanding into the modified vdW deposition lithography capabilities, we demonstrated a pn heterojunction using MoS₂/WSe₂ in a vdW-FET configuration, as shown in the schematics in FIG. 5a. Here, MoS₂ and WSe2 nanosheets were deposited first, followed by the anneal and heal treatment process for multiple cycles. FIG. 5b shows the measured IV_{ds} before and after the treatment process. The measured IV_{ds} curve after 2D deposition showed a poor rectification profile with current varying between 1 pA and 0.1 nA. However, after applying the anneal and heal treatment process, the device performance improved dramatically showing a diode behavior with a near-unity ideality factor (n=1.65±0.1) and current rectification ratio of 10². Table 2 shows comparison between ideality factor and current rectification of MoS₂/WSe₂ junctions reported in the literature.¹⁹⁻²³ FIG. 5c shows the fitted curve to the ideal diode equation using

$$I = {I}_{s} [ exp ( \frac{{eV}_{d s}}{nkT} ) - 1 ] ,$$

where Iₛ is the reverse saturation current, Tis the temperature, e is the electric charge, and k is the Boltzmann constant. FIG. 5d, e plots the evolution of the current rectification ratio and ideality factor with the “anneal and heal” treatment time, respectively. Although the current rectification of the device is comparable to other reports, the ideality factor reported here is one of the lowest, achieving a near-ideal diode behavior.

TABLE 2
Comparison of ideality factor and rectification
value for different MoS₂/WSe₂ junctions.

| | Ideality | Current | |
|---|---|---|---|
| Reference | Factor | Rectification | Notes |
| This work | 1.65 | 10\hat{ }2 | This work |
| [19] | 1.2 | 10\hat{ }2 | Gated at −20 V with dielectric of SiO₂ (300 nm). |
| [20] | 1.9 | 5 × 10\hat{ }4 | Further processing applied (CYTOP fluoropolymer |
| | | | encapsulation) to obtain high current values. |
| | | | Substrate is glass. |
| [21] | 2.23 | 5 × 10\hat{ }2 | Fluoropolymer passivation applied to the device. |
| | | | Substrate is glass. |
| [22] | 2.7 | 5 × 10\hat{ }2 | Ideality factor varies with gate voltage (−40 to |
| | | | 40 V) in the range of (3.2 to 2.6). Dielectric |
| | | | is SiO₂ (285 nm). |
| [23] | 1.68 | 10\hat{ }2 | Device fabricated on PET substrate. |

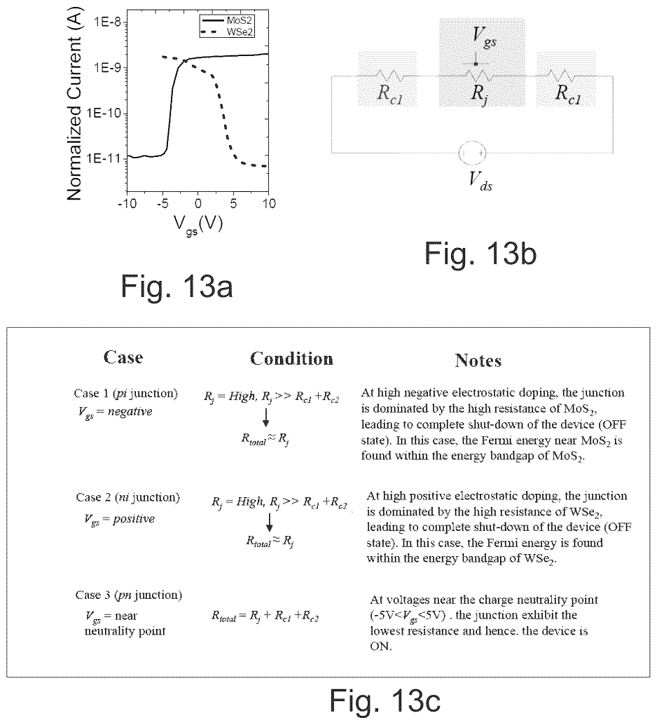

Apart from their fabrication simplicity with a near-unity ideality factor and high current rectification, what makes these MoS₂/WSe₂ vdW-FET diodes interesting is their gate-tunable capability. FIG. 5f demonstrates this gate tunable response before and after “anneal and heal” treatment process. Before treatment, the device exhibited extremely high resistance with very low current. However, after the treatment process, we observed two distinctive resistive regions, a high resistance region and a low resistance region. The high resistance region occurred when the device was gated in the negative regime (−10 V>V_{gs}>−4 V), giving rise to a current density lower than 0.01 A/cm², while the low resistive region occurred when the gate voltage varied between −4 V<V_{gs}<10 V, with a maximum current density up to 0.78 A/cm². The current change between these regions was on the order of 78×, offering a large current switching (I_{lowresistiveregion}/I_{highresistiveregion}) range. This gate tunable behavior observed in the MoS₂/WSe₂ vdW-FETs can be desirable for many low power switching applications and a key feature in tuning the photoresponsivity for in-sensor MV applications. FIG. 13 further explains this tunable electrostatic mechanism.

Highly Sensitive Gate-Tunable Optical Photodetector Using MoS₂/WSe₂ vdW-FETs. To enable in-sensor MV concepts by performing multiply and accumulation operations (MAC), an array of reconfigurable sensors with m×n elements can be connected as shown in FIG. 14. Each sensor element has a responsivity (Rₘₙ). With light being the external stimulation with power (P), it is possible to express the summation current as

$${I}_{n} = {\sum }_{n = 1}^{N} {I}_{m n} = {\sum }_{n = 1}^{N} {R}_{m n} {P}_{n} \qquad ( 1 )$$

Here, the multiplication in equation 1 is performed at the individual sensor level. Accordingly, it is essential that each individual sensor exhibits tunable photoresponsivity (or responsivity hereafter) with external modulation, such as gate voltage, which emulates the synaptic weight of a neural network. This concept of in-sensor MV is new and differs from near-sensor MV where optical sensors are connected to an array of memory devices to perform the computing, as discussed elsewhere.²

To the best of our knowledge, very few reports have demonstrated in-sensor MV using this principle. Most notable is the work reported by Mennel et al. where they demonstrated in-sensor MV using a self-powered split-gate WSe₂ photodetector in a floating gate configuration.⁶ The split gate WSe₂ photodetector exhibited tunable responsivity by changing the electrostatic doping. Nevertheless, most reports utilize a near-sensor computing scheme instead of in-sensor computing, as will be discussed later.

One can deduce that optimizing the photodetector requirements is a vital step toward CMOS integrable in-sensor MV. As such, in addition to the tunable responsivity requirement and to enable multifunctional optical sensors on a CMOS platform for MV applications, any photodetector element should exhibit the following requirements: (1) scalable and cost-effective fabrication techniques for BEOL integration on the CMOS platform, (2) reconfigurable high responsivity with a high degree of tunability using an external voltage (high gate tuning ratio), (3) white light detection to enable a wide range of wavelength detection, and most importantly, (4) ultralow power consumption. Accordingly, identifying a photodetector that can meet all these requirements is a vital step before integrating any photodetector element for in-sensor MV (i.e., using a floating gate structure).

To date, no photodetector devices used for in/near-sensor computing can meet all of these stringent requirements. In fact, most published reports use methods and techniques that are either hard to scale up or are CMOS incompatible.^{24,25} These methods include the use of electron beam lithography, nonconventional substrates, or expensive fabrication processes.²⁶⁻²⁸ Moreover, all reports show devices with noticeable power dissipation, which can affect the total performance.^{7,25,29-33} Some reports show photodetectors with low responsivity or low gate tunability.³⁴⁻³⁹ However, other reports require double gate configuration structures (i.e., split gate) to obtain tunable responsivity.^{6,40-42} Additionally, most reports on photodetectors utilized for in/near-sensor computing are aimed at specific wavelength detection and not the entire visible range.

Using modified vdW deposition lithography, we demonstrate a one-of-a-kind photodetector that can fulfill the requirements stated above. The photodetector utilized a MoS₂/WSe₂ junction fabricated on a SiO₂/Si substrate, as shown in FIG. 6a. The measured IV_{ds} characteristics before and after LED white light illumination (P=8 mW/cm²) are shown in FIG. 6b,c for V_{gs}=5 V and V_{gs}=−19 V, respectively. The inset of each figure shows the obtained photocurrent (Iₚₕ=I_{light}−I_{dark}) plotted against Vas. Under V_{gs}=5 V, the highest photocurrent magnitude was obtained, with the maximum occurring in the reverse bias. However, when the applied gate voltage was V_{gs}=−19 V, the photocurrent was remarkably suppressed by 9.68 and 6.625 orders of magnitude in the reverse bias (at V_{ds}=−100 mV) and zero Vas, respectively. This photocurrent modulation is a key feature in obtaining gate-tunable responsivity for in-sensor MV.

To gain a deeper understanding of the MoS₂/WSe₂ photodetector performance, we show the obtained photo-responsivity (sometimes referred to as the responsivity) and specific detectivity of the device at different applied Vds and Vgs in FIG. 6d,e, respectively. FIG. 15 shows some sampled IVds curves in the dark and under white light illumination, respectively. The highest responsivity occurred when the device was reverse biased (at Vds=100 mV) and gated at Vgs=5 V. In contrast, the highest detectivity was obtained when the device was self-powered (Vds=0 V) and gated at Vgs=5 V. This can be clearly seen in FIG. 15d,e where the responsivity and detectivity are plotted for V_{ds}=0 V and V_{ds}=−100 mV, respectively. Accordingly, these measurements serve as a demonstration of photoresponsivity tunability using a single gate structure of the MoS₂/WSe₂ device.

Based on these results, one can deduce that the photodetector can operate under two different modes, photovoltaic mode, and photoconductive mode. In photovoltaic mode (or self-power photodetector), the applied V_{ds} is zero and a short circuit current (Isc) is generated under white light illumination. The rise and fall times of the photodetector under this mode are shown in FIG. 16 and were estimated to be 25 and 8 ms, respectively. However, when reverse voltage is applied, additional photogenerated carriers are created, leading to higher photocurrent. In both cases, the responsivity can be tuned by 6.6× for photovoltaic mode and 9.7× for photo-conductive mode, as shown in FIG. 15c,d. Here, the device exhibited a high gate tuning ratio of 38.2 and 53.5 mA/V for the photovoltaic mode and photoconductive mode, respectively.

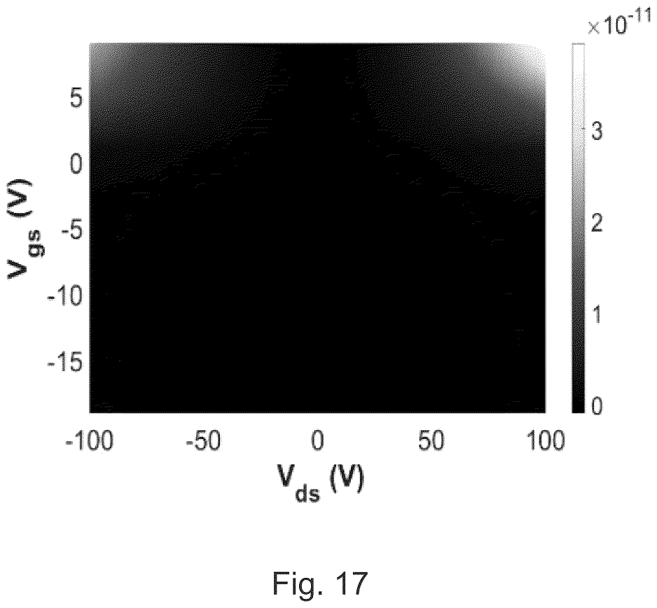

The power dissipation of this device is shown in FIG. 17 at different V_{ds} values and Vgs. Here, power dissipation is defined as Pd=I_{dark}V_{ds} at any given V_{gs}. Under the photovoltaic mode, the dissipated power is zero, and a short circuit current is generated (power generation instead of power dissipation). However, under the photoconductive mode, the power dissipation is not zero, and high dark current can lead to high power dissipation. Thus, to optimize power dissipation, devices operating under photovoltaic mode with tunable responsivity are favorable for in-sensor MV.

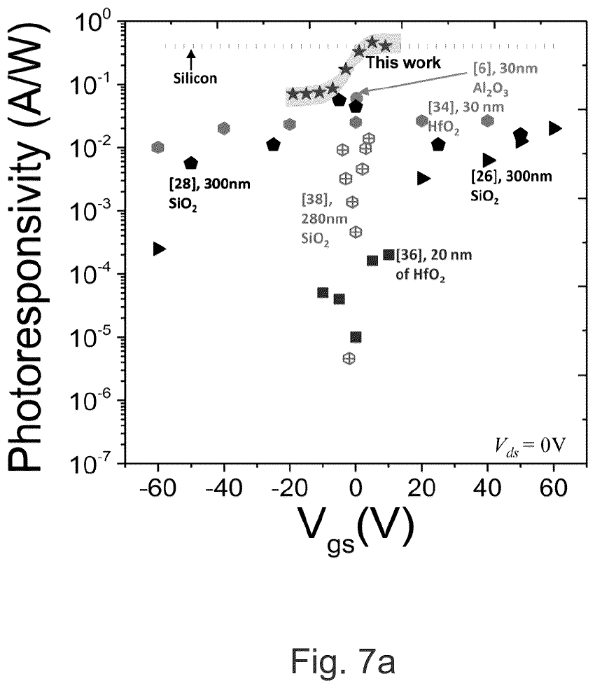

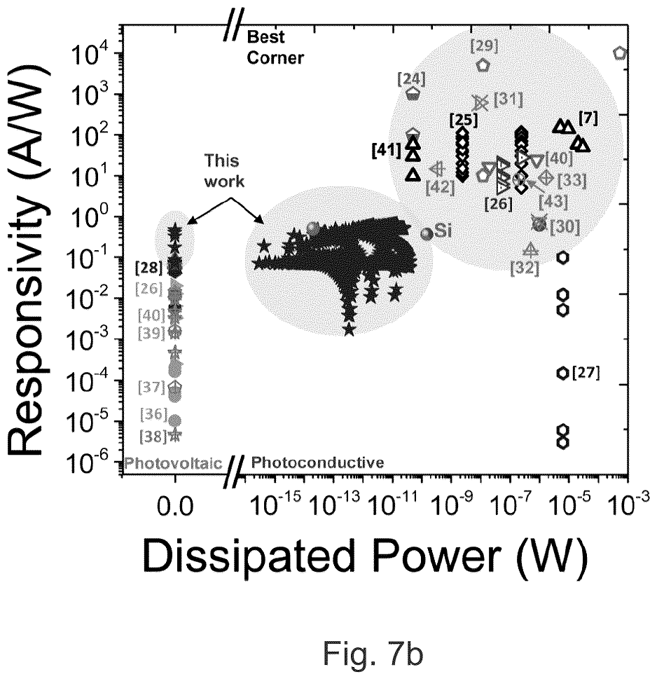

The performance of our device supersedes that of reported photovoltaic devices when operating under photovoltaic mode, as shown in the benchmark plot in FIG. 7a. Here, the device performance (responsivity vs V_{gs}) is plotted from reports utilizing gate-tunable photovoltaic devices for MV.6,26,28,34,36-38,43 The highest responsivity reported to date ranges between 0.05 and 0.06 A/W. These reports utilize a specific wavelength detection while white light MV photovoltaic devices show responsivities that range between 0.009 and 0.0137 A/W. In contrast, our device shows superior responsivity with the highest reaching 0.45 A/W with high gate tunability.

The power dissipation parameter is a vital factor for scalable in-sensor or near-sensor MV applications. In FIG. 7b, we benchmark our device with prominent MV photodetectors reported in the literature by plotting the responsivity vs dissipated power.^{7,24-27,29-33,39,44-46} Here, various photo-detector technologies reported for MV are being compared to our device, including InP, CsPbBr₃ perovskite, and BiFeO₃. White light photodetectors are also included in this benchmark and plotted as unfilled dots with crossed marks.

Based on this, our device surpasses all photovoltaic devices analogues to FIG. 7a. More importantly, when our device operates under photoconductive mode, the obtained device performance shows high responsivity with exceptionally low power dissipation. The highlighted area in pink of FIG. 7b shows the region of operation of our phototransistor operating under photodetector mode. This region is comparable to commercial silicon photodiodes with an exceptionally low dark current. While other reports show high responsivities, they all fail in the power dissipation requirement. This is due to the required bias voltage needed to obtain high photogenerated carriers, which is associated with a noticeably large dark current. Due to the modified vdW deposition lithography, efficient photogenerated carrier extraction was achieved using a MoS₂/WSe₂ in a vdW-FET configuration.

Although these reports show noticeably higher power dissipation compared to our device, they also fail to create scalable and low-cost fabrication processes. As stated above, most reports use electron beam lithography or other means of complicated or expensive lithography processes, which can hinder the integration of these devices for large scale applications. Yet, authors understand that several groups use this method to demonstrate proof-of-concept devices only.

The use of optical lithography coupled with modified vdW deposition lithography is a desirable route to produce scalable, high-performance, and cost-effective 2D transistors. In principle, we believe this vdW deposition lithography technique can be applied to wafer scale 2D materials such as chemical vapor deposition (CVD)-grown MoS₂ and WSe₂. Here, wafer scale 2D semiconductors need to be transferred to our patterned substrate. Various defect-free transfer methods have been investigated in the literature.⁴⁷ Such work will be investigated in the future to perform high-level image processing. Nonetheless, the work presented here serves as the backbone for a proof-of-concept photodetector based on modified vdW deposition lithography for BEOL MV and will be used for comparison with CVD grown 2D materials.

### CONCLUSIONS

vdW-FETs were fabricated using modified vdW deposition lithography. This strategy enabled us to create low-cost, scalable, energy efficient, and high-performance BEOL phototransistors for in-sensor MV applications. We showed that vdW deposition lithography alone cannot produce high-performance devices due to large device resistance attributed to weak bonding between the 2D material and metal electrodes. However, incorporating “anneal and heal” treatment process produced low device resistance with high current density. This lithography technique enabled us to eliminate FLP, which is a major challenge in 2D-FETs. This strategy was utilized to produce gate-tunable near-ideal diode behavior using MoS₂/WSe₂ vdW-FETs with an ideality factor of 1.65 and current rectification of 10². Finally, we demonstrated a one-of-a-kind gate-tunable photodetector using MoS₂/WSe₂ vdW-FETs. This photodetector operated in two different modes, the photovoltaic mode and photoconductive mode. Under photo-voltaic mode, the device exhibited gate-tunable responsivities reaching 0.45 A/W with responsivity modulation of 6.6×. Under photoconductive mode, the photodetector showed responsivities up to 0.68 A/W with responsivity modulation of 9.68×. This photodetector performance was benchmarked with other reported photodetectors used for in- and near-sensor MV applications. We deduced that our photodetector exhibited superior performance compared to other reported photodetectors utilized in MV applications by considering the requirements for in-sensor MV. Broadly, our work demonstrated a novel method to create BEOL 2D transistors for CMOS-compatible multifunctional sensor applications, enabling CMOS+2D.

### Methods and Materials

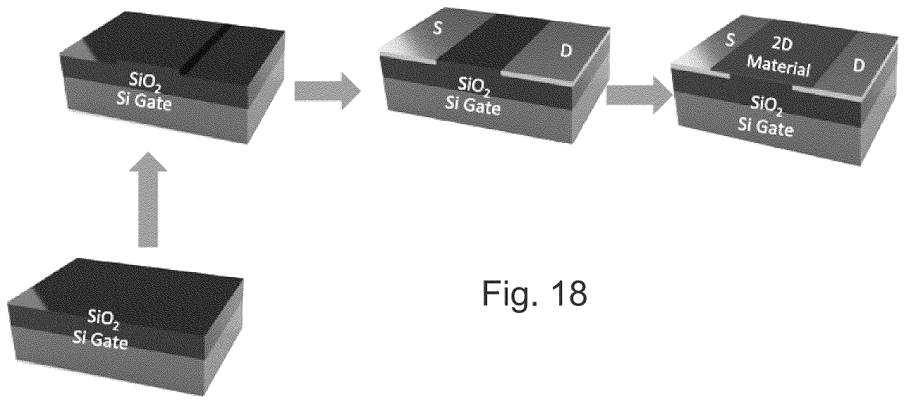

Device Fabrication. vdW-FETs devices were fabricated by using SiO₂ (300 nm) grown on a Si substrate. Source and drain electrodes were first patterned using optical lithography followed by a 100 nm electrode deposition. 2D nanosheets (from 2D semiconductor) were mechanically exfoliated using a special exfoliation tape followed by micro alignment to the prepatterned substrate using a customized dry transfer setup. Optical inspection, Raman measurements, and IV measurements were carried out to confirm the contact of the deposited nanosheet with the source and drain electrodes. The substrate was thoroughly cleaned with acetone, IPA, and deionized water, followed by nitrogen flow to ensure the cleanliness of the surface prior to 2D material deposition. FIG. 18 schematically shows the fabrication process. For the heterojunction device in FIG. 6, multilayer MoS₂ and WSe₂ were used to cover the entire white light spectrum.

### Anneal and Heal Treatment Process

Fabricated chips were placed on top of a hot plate in ambient for 2-5 s where a global thermal pulse was applied in the range between 30° and 350° C. Chips were removed directly after the annealing cycle and left at room temperature for a few seconds to cool down. Optical examination of the substrate before and after annealing does not show any changes to the substrate nor the deposited 2D material. However, repeating the annealing cycles will produce degraded device performance and structural damage to the deposited 2D material, especially MoS₂ where the first treatment cycle will always yield the best device performance for all devices measured in this study. It has been shown that different treatment cycles can produce degraded device performance if prolonged treatment cycles are applied to MoS₂ devices. Moreover, repeating this treatment cycle for a prolonged time will induce defects and permanent damage on the surface of 2D materials, as evident by an optical microscopy investigation. It should be noted that applying a lower temperature than the range specified above will yield no device improvements, while higher temperatures will yield higher contact resistance and structural damages to the device from the first annealing cycles.

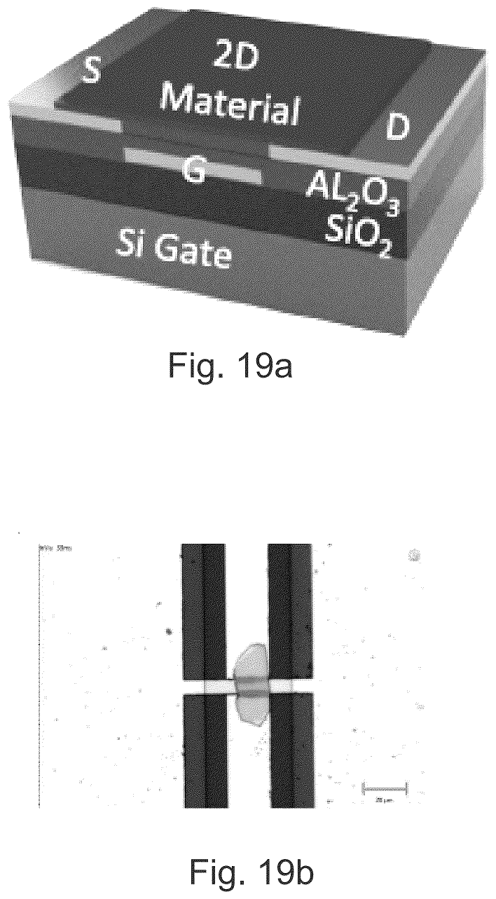

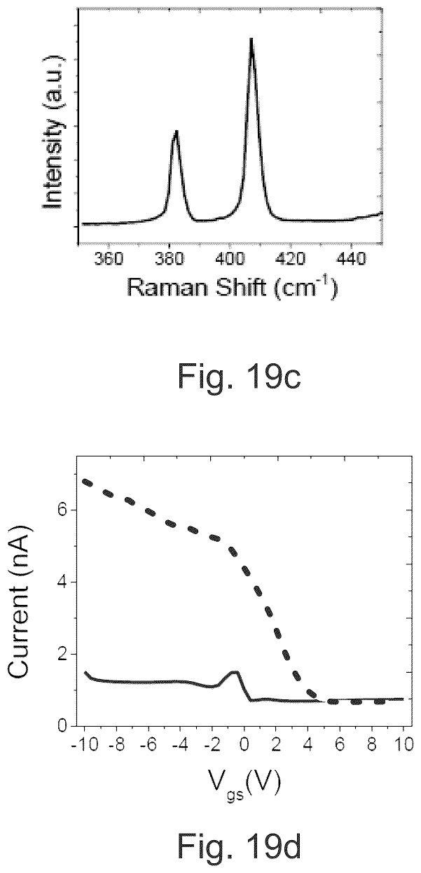

For the MoS₂—Au devices, the gold electrode work function falls in the midgap of MoS₂ with no band alignment. This causes no current flow, as observed in many devices before treatment. The anneal and heal treatment process seems to eliminate barriers between the metal and 2D material, including defects. However, the origin of the full mechanism of alignment with the conduction band minimum (CBM) is not fully understood yet. One possible explanation is that due to the substrate doping effect caused by trapped charges in SiO₂, it is favorable for the MoS₂ CBM to align with the Au work function, giving rise to a strong vdW contact with n-type conductivity. This effect has been observed in previous report.¹⁰ In fact, when fabricating devices on a different dielectric (Al₂O₃), it is possible to get p-type conductivity as shown in FIG. 19, which is further evidence of induced doping of SiO₂. It also demonstrates that the “anneal and heal” treatment process produces weak FLP. Yet, further analysis into the dynamics of band alignment after the treatment process should be explored in the future.

Unlike MoS₂ devices, where the maximum device performance occurs readily after the first treatment cycle, other 2D materials such as WSe₂ and BP show device enhancement occurring after multiple treatment cycles.

Optical and Morphology Characterization. Each sample was characterized using confocal Raman spectroscopy (Renishaw) with a silicon detector and 2400 l/mm grating. We used the 532 nm laser line to excite Raman modes of our 2D materials. To avoid overheating, we used laser power up to 0.93 mW for a laser spot size of ~1.5 μm. The 100× objective lens was used for all Raman measurements. Morphology measurements were carried out using a Park Systems XE7. We use noncontact mode to ensure no induced defects/changes to the deposited nanosheets on our devices. Optical and AFM images were compared before and after measurements to ensure that the device was intact without any structural changes.

Electrical Characterization. Current-voltage characteristics were measured using Keysight B1500 with the source, drain, and gate electrodes connected to three different micromanipulators. IV_{ds} and IV_{gs} measurements were carried out with current sensitive modules (down to 1 fA sensitivity). Measurements were carried out at room temperature and in ambient conditions. Before and after each electrical measurement, optical inspection and Raman measurements were carried out to identify any change in the structure. Due to the existence of trapped charges in the oxide, the gate voltage range was adjusted to resolve the turn-on and turn-off range of each vdW-FET device.

### Photodetector Characterization

Photo-IVs in the dark and under light illumination were carried out in ambient conditions using our probe station setup. The chip was probed prior to any annealing and IV measurements in the dark and under LED white light (OMAX20 W) illumination. V_{ds} and V_{gs} were varied to obtain the current maps. The anneal and heal treatment process was subsequently applied to the chip, and the photo-IV measurements in the dark and under white light illumination were carried out. This process was repeated for every anneal and heal treatment cycle until a lower value in the maximum current was obtained.

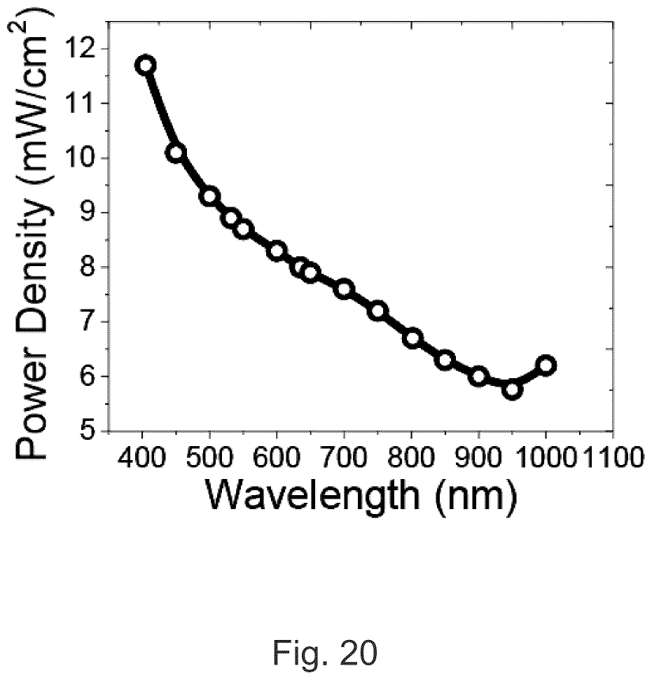

Responsivity and Detectivity Calculations. The responsivity (R) is given by (R=Iₚₕ/Pₒₚ), where Iₚₕ is the photocurrent (in units of mA/cm²) and Pₒₚ is the optical power incident on the photodetector (in units of mW/cm²). The calculated specific detectivity (D* in units of jones) of the photodetector is given by D*=RA^{1/2}/(2eI_{dark})^{1/2}, where A is the effective area of the junction. To obtain accurate responsivity values, the optical power density of the LED white light was characterized using an optical power meter (Thorlabs PM400 and S120C). The power density vs wavelength was characterized as shown in FIG. 20. The total power density of the white light was measured using the irradiance mode (in units of mW/cm²) at the exact location of the device. The obtained power density was found to be 8 mW/cm².

### In-Sensor Edge Detection Extraction for Intelligent Machine Vision:

Edge detection constitutes a fundamental component within intelligent machine-vision architectures by serving as an early-stage computational mechanism that extracts relevant structural features directly at the point of sensing. By emphasizing intensity discontinuities, object contours, and spatial gradients, edge extraction substantially reduces the dimensionality of raw visual data and provides a compact representation that is inherently more informative for subsequent machine-learning or AI-based inference. This hierarchical organization parallels biological vision systems, in which the retina performs initial feature encoding to alleviate computational load on higher cortical layers. Within modern intelligent and in-sensor machine-vision paradigms, edge detection therefore functions as a critical front-end processing stage that enhances efficiency, lowers power consumption, and improves real-time responsiveness by delivering an optimized, feature-rich input to downstream intelligent processing units.

To illustrate the power of in-sensor computing using our 2D heterojunctions, we test the performance of the developed phototransistor reported in the manuscript numerically. Referring to FIG. 21, we use the photoresponsivity gate dependence measurements (FIG. 6d) and map it to pixel-level image processing, bridging the physical device characteristics with machine vision behavior. The phototransistor's optical sensitivity is mapped across 128×128 image. The resulting photoresponse image, generated by weighting each pixel's intensity by its local responsivity, mimics how a physical array of transistors would differentially amplify or suppress light in real-time. FIG. 21b shows the measured photocurrent of Lenna image (FIG. 21a is a standard test image used in digital image processing) under ideal conditions (no noise) and the resultant edge detection images obtained after applying edge detection (FIG. 21c). One can see that the processed image resolves the edges of the original signal successfully, which demonstrates the power of the reported phototransistors in the published manuscript.

To emulate natural operating environments, a noise component was added (Gaussian noise with 5% amplitude noise). The noisy photoresponse was then convolved with a suite of spatial filters to produce edge detection. The results in FIGS. 21d-21e reveal that the gate-weighted photoresponse produces strong, gate-dependent contrast enhancement along the image edges. At moderate gate voltages, where the device exhibits peak responsivity, edges become pronounced and continuous, while at higher negative biases, the response attenuates, effectively suppressing background noise. This behavior demonstrates that our phototransistor can act not only as a light detector but as an adaptive optical pre-processor, dynamically tuning image contrast, and feature extraction through simple bias modulation.

These simulated results demonstrate a core feature of the reported vdW-FET phototransistor where its voltage-dependent responsivity acts as an analog weighting mechanism, enabling it to perform MAC operations in convolutional neural networks. When extended to larger phototransistor matrices, this principle supports real-time image analysis and pattern recognition using hardware physics alone, leading to a new generation of in-sensor neuromorphic processors.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

### REFERENCES

1. Lemme, M. C. et al. “2D materials for future heterogeneous electronics.” Nat. Commun. 13, 1392 (2022).
2. Zhou, F.; Chai, Y. “Near-sensor and in-sensor computing.” Nat. Electron. 3, 664-671 (2020).
3. Liao, F.; Zhou, F.; Chai, Y. “Neuromorphic vision sensors: Principle, progress and perspectives.” J. Semicond. 42, 013105 (2021).
4. Choi, C.; Seung, H.; Kim, D.-H. “Bio-inspired electronic eyes and synaptic photodetectors for mobile artificial vision.” J-FLEX 1, 76-87 (2022).
5. Bian, J.; Cao, Z.; Zhou, P. “Neuromorphic computing: Devices, hardware, and system application facilitated by two-dimensional materials.” Appl. Phys. Rev. 8, 041313 (2021).
6. Mennel, L. et al. “Ultrafast machine vision with 2D material neural network image sensors.” Nature 579, 62-66 (2020).
7. Jang, H. et al. “An atomically thin optoelectronic machine vision processor.” Adv. Mater. 32, 2002431 (2020).
8. Liu, K. et al. “An optoelectronic synapse based on α-In₂Se₃ with controllable temporal dynamics for multimode and multiscale reservoir computing.” Nat. Electron. 5, 761-773 (2022).
9. Huang, B. et al. “Optoelectronic Synapses Based on MoS2 Transistors for Accurate Image Recognition.” Adv. Mater. Interfaces 9, 2201558 (2022).
10. Liu, Y. et al. “Approaching the Schottky-Mott limit in van der Waals metal-semiconductor junctions.” Nature 557, 696-700 (2018).
11. Shen, P.-C. et al. “Ultralow contact resistance between semimetal and monolayer semiconductors.” Nature 593, 211-217 (2021).
12. Li, W. et al. “Approaching the quantum limit in two-dimensional semiconductor contacts.” Nature 613, 274-279 (2023).
13. Liu, Y.; Stradins, P.; Wei, S.-H. “Van der Waals metal-semiconductor junction: Weak Fermi level pinning enables effective tuning of Schottky barrier.” Sci. Adv. 2, e1600069 (2016).
14. Kim, G.-S. et al. “Schottky barrier height engineering for electrical contacts of multilayered MoS2 transistors with reduction of metal-induced gap states.” ACS Nano 12, 6292-6300 (2018).
15. Liu, H.; Neal, A. T.; Ye, P. D. “Channel length scaling of MoS₂ MOSFETs.” ACS Nano 6, 8563-8569 (2012).
16. Kang, J.; Liu, W.; Banerjee, K. “High-performance MoS2 transistors with low-resistance molybdenum contacts.” Appl. Phys. Lett. 104, 093106 (2014).
17. English, C. D. et al. “Improved contacts to MoS2 transistors by ultra-high vacuum metal deposition.” Nano Lett. 16, 3824-3830 (2016).
18. Sebastian, A. et al. “Benchmarking monolayer MoS₂ and WS₂ field-effect transistors.” Nat. Commun. 12, 693 (2021).
19. Cheng, R. et al. “Electroluminescence and photocurrent generation from atomically sharp WSe₂/MoS₂ heterojunction p-n diodes.” Nano Lett. 14, 5590-5597 (2014).
20. Jeon, P. J. et al. “Enhanced device performances of WSe₂—MoS₂ van der Waals junction p-n diode by fluoropolymer encapsulation.” J. Mater. Chem. C 3, 2751-2758 (2015).
21. Cho, A.-J. et al. “Two-dimensional WSe₂/MoS₂ p-n heterojunction-based transparent photovoltaic cell and its performance enhancement by fluoropolymer passivation.” ACS Appl. Mater. Interfaces 10, 35972-35977 (2018).
22. Kim, Y. et al. “2D transition metal dichalcogenide heterostructures for p- and n-type photovoltaic self-powered gas sensor.” Adv. Funct. Mater. 30, 2003360 (2020).
23. Lin, P. et al. “Piezo-phototronic effect for enhanced flexible MoS₂/WSe₂ van der Waals photodiodes.” Adv. Funct. Mater. 28, 1802849 (2018).
24. Seo, S. et al. “Artificial optic-neural synapse for colored and color-mixed pattern recognition.” Nat. Commun. 9, 5106 (2018).
25. Tao, J. et al. “Machine Vision With InP Based Floating-Gate Photo-Field-Effective Transistors for Color-Mixed Image Recognition.” IEEE J. Quantum Electron. 58, 1-7 (2022).
26. Mukherjee, S. et al. “Monolithic In₂Se₃—In₂O₃ heterojunction for multibit non-volatile memory and logic operations using optoelectronic inputs.” npj 2D Mater. Appl. 6, 37 (2022).
27. Fu, X. et al. “Graphene/MoS₂-xOₓ/graphene photomemristor with tunable non-volatile responsivities for neuromorphic vision processing.” Light Sci. Appl. 12, 39 (2023).
28. Li, D. et al. “Gate-Controlled BP-WSe2 Heterojunction Diode for Logic Rectifiers and Logic Optoelectronics.” Small 13, 1603726 (2017).
29. Zhen, W. et al. “Ultrasensitive, ultrafast, and gate-tunable two-dimensional photodetectors in ternary rhombohedral ZnIn₂S₄ for optical neural networks.” ACS Appl. Mater. Interfaces 14, 12571-12582 (2022).
30. Maria, C. C. S. et al. “White-light photodetection enhancement and thin film impediment in Bi₂S₃ nanorods/thin-films homojunction photodetectors.” Appl. Surf. Sci. 584, 152608 (2022).
31. Zhou, W. et al. “Ultrahigh sensitivity and gain white light photodetector based on GaTe/Sn:CdS nanoflake/nanowire heterostructures.” Nanotechnology 25, 445202 (2014).
32. Rana, J. S.; Das, S.; Jit, S. “Highly Responsive Al/PTB7/Si/Al Vertical Structure-Based White Light Photodetector Using FTM Method.” IEEE Photonics Technol. Lett. 35, 765-768 (2023).
33. Yadav, S. M.; Pandey, A. “An efficient white-light photodetector based on 2D-SnS₂ nanosheets.” IEEE Trans. Electron Devices 69, 1889-1893 (2022).
34. Yang, Z. et al. “WSe₂/GeSe heterojunction photodiode with giant gate tunability.” Nano Energy 49, 103-108 (2018).
35. Li, D. et al. “Two-dimensional non-volatile programmable p-n junctions.” Nat. Nanotechnol. 12, 901-906 (2017).
36. Baugher, B. W. et al. “Optoelectronic devices based on electrically tunable p-n diodes in a monolayer dichalcogenide.” Nat. Nanotechnol. 9, 262-267 (2014).
37. Dhakshnamoorthy, M. et al. “Self-powered white light photodetector with enhanced photoresponse using camphor sulphonic acid treated CsPbBr₃ perovskite in carbon matrix.” Mater. Lett. 341, 139534 (2023).
38. Molina-Mendoza, A. J.; Paur, M.; Mueller, T. “Nonvolatile programmable WSe₂ photodetector.” Adv. Opt. Mater. 8, 2000417 (2020).
39. Rana, A. K. et al. “Transparent Co₃O₄/ZnO photovoltaic broadband photodetector.” Mater. Sci. Semicond. Process. 117, 105192 (2020).
40. Yang, Y. et al. “In-sensor dynamic computing for intelligent machine vision.” Nat. Electron. 7, 225-233 (2024).
41. Wang, Y. et al. “Van der Waals contacted WSe₂ ambipolar transistor for in-sensor computing.” Nano Res. 16, 12713-12719 (2023).
42. Wu, L. et al. “Visible-to-mid-infrared in-sensor computing with a reconfigurable black phosphorus photodiode.” IEEE Electron Device Lett. 45, 1217-1220 (2024).
43. Kathirvel, A.; Uma Maheswari, A.; Sivakumar, M. “Highly sensitive and wavelength-tunable solution-processed BiFeO₃ heterojunction based fast-response self-powered white-light photodetector.” Thin Solid Films 761, 139534 (2022).
44. Wang, C.-Y. et al. “Gate-tunable van der Waals heterostructure for reconfigurable neural network vision sensor.” Sci. Adv. 6, eaba6173 (2020).
45. Guo, Y. et al. “Air-stable and solution-processable perovskite photodetectors for solar-blind UV and visible light.” J. Phys. Chem. Lett. 6, 535-539 (2015).
46. Fang, H. et al. “A self-powered organolead halide perovskite single crystal photodetector driven by a DVD-based triboelectric nanogenerator.” J. Mater. Chem. C 4, 630-636 (2016).
46. Quellmalz, A. et al. “Large-area integration of two-dimensional materials and their heterostructures by wafer bonding.” Nat. Commun. 12, 917 (2021).

What is claimed is:

1. A phototransistor comprising:
a substrate;
a gate electrode disposed over the substrate;
a gate dielectric layer disposed over the gate electrode;
a source electrode and a drain electrode disposed over the gate dielectric layer; and
a channel layer bridging the source electrode and the drain electrode, the channel layer being composed of at least one van der Waals (vdW) two-dimensional material and contacting top surfaces of the source electrode and the drain electrode to form a van der Waals interface, wherein the phototransistor exhibits gate-tunable photoresponsivity enabling operation in both a photovoltaic mode and a photoconductive mode.

2. The phototransistor of claim 1, wherein at least one van der Waals two-dimensional material is composed of a component selected from the group consisting of molybdenum disulfide (MoS₂), tungsten diselenide (WSe₂), and combinations thereof.

3. The phototransistor of claim 1, wherein the channel layer includes a heterojunction formed by a first two-dimensional material and a second two-dimensional material.

4. The phototransistor of claim 3, wherein the first two-dimensional material comprises molybdenum disulfide (MoS₂) and the second two-dimensional material comprises tungsten diselenide (WSe₂), forming a heterojunction.

5. The phototransistor of claim 3, wherein the heterojunction provides a tunable photo responsivity and efficient charge separation for high-performance phototransistors and optoelectronic applications.

6. The phototransistor of claim 1, wherein the phototransistor is annealed and healed to exhibit a low-bias resistance that is proportional to channel length, with an on/off current ratio (Iₒₙ/Ioff) of at least 10² and an enhanced turn-on current density (Iₒₙ) by a factor of at least 30 compared to an FET phototransistor not treated with an “anneal and heal” thermal treatment process.

7. The phototransistor of claim 1, fabricated by a vdW deposition lithography process comprising patterning with optical lithography, depositing of the source electrode and the drain electrode and placing the channel layer over the source electrode and the drain electrode, followed by application of “anneal and heal” thermal treatment to reduce contact resistance between the channel layer and the source electrode and the drain electrode and to mitigate Fermi level pinning.

8. The phototransistor of claim 7, wherein the anneal and heal process comprises exposing the phototransistor to pulsed thermal treatment at a temperature of 300° C. to 350° C. for a duration of 2 to 5 seconds.

9. The phototransistor of claim 1, wherein, in the photovoltaic mode, the phototransistor generates a short-circuit current under illumination at zero drain-source voltage;
and in the photoconductive mode, the phototransistor operates under reverse bias to achieve enhanced photoresponsivity.

10. The phototransistor of claim 9, wherein in the photovoltaic mode, the phototransistor generates a gate-tunable photoresponsivity of up to 0.45 A/W with a responsivity modulation of at least 6.6 fold.

11. The phototransistor of claim 9, wherein in the photoconductive mode, the phototransistor achieves a responsivity of up to 0.68 A/W with a responsivity modulation of at least 9.68 fold.

12. The phototransistor of claim 1, configured to detect white light illumination with gate-tunable photoresponsivity and ultra-low power dissipation.

13. The phototransistor of claim 1, wherein the gate electrode enables switching between high and low resistive states in the channel layer with a resistance change of at least 44-fold.

14. A reconfigurable optical sensor array for in-sensor machine vision applications, comprising:
a plurality of sensor elements arranged in an m×n array where m is the number of sensor elements in a first linear direction and n is the number of sensor elements in a second linear direction, wherein each sensor element comprises a phototransistor according to claim 1, wherein each sensor element exhibits independently tunable photoresponsivity controllable by a gate voltage applied thereto.

15. A photodetector device comprising:
a substrate having a gate electrode and a gate dielectric layer disposed thereover;
a source electrode and a drain electrode formed on the gate dielectric layer; and
a channel comprising a van der Waals (vdW) heterojunction of MoS₂ and WSe₂ bridging the source electrode and the drain electrode, wherein the gate electrode is operably configured to modulate photocurrent in the channel, and the photodetector device exhibits gate-tunable responsivity for white light detection with ultra-low power dissipation.

16. The photodetector device of claim 15, wherein the device operates in a photovoltaic mode to generate a short-circuit current under illumination with no power dissipation.

17. The photodetector device of claim 15, wherein the device operates in a photoconductive mode to achieve enhanced photoresponsivity under reverse bias conditions.

18. A method of fabricating a field-effect transistor (FET) phototransistor, comprising:
providing a substrate comprising a gate electrode and a gate dielectric layer disposed over the gate electrode;
depositing a source electrode and a drain electrode on the gate dielectric layer;
placing a channel layer over and in contact with the source electrode and the drain electrode to bridge the source electrode and the drain electrode, the channel layer being composed of at least one van der Waals (vdW) two-dimensional material; and
subjecting the phototransistor to an anneal and heal treatment process comprising applying a thermal pulse to reduce device resistance and increase electronic coupling between the channel layer and the source electrode and drain electrode.

19. The method of claim 18, wherein anneal and heal treatment process comprises:
exposing the channel layer to a thermal pulse at a temperature of approximately 300° C. to 350° C. for 2 to 5 seconds; and
allowing the channel layer to cool.

20. The method of claim 18, wherein the channel layer includes a heterojunction including a first two-dimensional material and a second two-dimensional material to form a heterojunction channel between the source electrode and the drain electrode.

21. The method of claim 20, wherein the first two-dimensional material comprises molybdenum disulfide (MoS₂) and the second two-dimensional material comprises tungsten diselenide (WSe₂), forming a heterojunction.

22. The method of claim 18, wherein the source electrode and the drain electrode are formed by patterning with optical lithography followed by deposition of metals for the source electrode and the drain electrode.

23. The method of claim 18, wherein the at least one van der Waals (vdW) two-dimensional material is deposited onto the substrate using a dry transfer method.

24. The method of claim 18, wherein the anneal and heal treatment is repeated for multiple cycles to optimize the device resistance and photoresponsivity.

25. The method of claim 18, wherein the anneal and heal process eliminates Fermi level pinning and enhances coupling between the source electrode and the drain electrode and the channel layer.

26. The method of claim 18, further comprising encapsulating the phototransistor with a protective layer after the anneal and heal treatment to preserve its performance.

27. The method of claim 18, wherein the phototransistor is configured for operation in photovoltaic and photoconductive modes by tuning a gate voltage after fabrication.

28. The method of claim 18, wherein a thermal pulse in the anneal and heal process is applied in an ambient environment to avoid structural degradation of channel layer.

29. The method of claim 18, wherein the gate dielectric layer comprises silicon dioxide (SiO₂) with a thickness of approximately 300 nm.

30. The method of claim 18, further comprising characterizing electrical performance of the phototransistor by measuring current-voltage characteristics before and after the anneal and heal treatment.
